(19) United States
(12) Patent Application Publication
(10) Pub. No.: US 2026/0114129 A1
(43) Pub. Date: Apr. 23, 2026

(54) DISPLAY DEVICE, ELECTRONIC DEVICE AND METHOD FOR FABRICATING THE SAME

(71) Applicant: Samsung Display Co., Ltd., Yongin-si (KR)

(72) Inventors: Myeong Hun SONG, Yongin-si (KR); Gun Shik KIM, Yongin-si (KR); Sang Yeol KIM, Yongin-si (KR); Jin Yong KIM, Yongin-si (KR); Bong Chun PARK, Yongin-si (KR); Seung Woo SEO, Yongin-si (KR); Ji Hyun HAM, Yongin-si (KR)

(21) Appl. No.: 19/265,937

(22) Filed: Jul. 10, 2025

(30) Foreign Application Priority Data
Oct. 18, 2024 (KR) 10-2024-0142618

(51) Int. Cl. H10K 59/122; H10K 59/131; H10K 59/80

(52) U.S. Cl. CPC H10K 59/122; H10K 59/873; H10K 59/131; H10K 59/8794

(57) ABSTRACT

A display device includes: a substrate; a first electrode in a display area of the substrate; a light emitting layer on the first electrode; a pixel defining film on the light emitting layer; a second electrode on the pixel defining film; and a flow control layer including: a first main groove in a non-display area of the substrate; a second main groove in the non-display area; and an auxiliary groove in the non-display area between the first main groove and the second main groove.

### CROSS-REFERENCE TO RELATED APPLICATION

The present application claims priority to and the benefit of Korean Patent Application No. 10-2024-0142618, filed on Oct. 18, 2024, in the Korean Intellectual Property Office, the entire disclosure of which is incorporated by reference herein.

### BACKGROUND

### 1. Field

Aspects of embodiments of the present disclosure relate to a display device, an electronic device including the display device, and a method for fabricating the display device.

### 2. Description of the Related Art

An organic light emitting display apparatus includes display elements having a luminance that varies depending on an electric current, for example, such as organic light emitting diodes.

The organic light emitting display apparatus includes a plurality of pixels that provide different light (e.g., different colored light) from one another.

### SUMMARY

Embodiments of the present disclosure may be directed to a display device capable of controlling a flow of an encapsulation organic film, an electronic device including the display device, and a method for fabricating the display device.

According to one or more embodiments of the present disclosure, a display device includes: a substrate; a first electrode in a display area of the substrate; a light emitting layer on the first electrode; a pixel defining film on the light emitting layer; a second electrode on the pixel defining film; and a flow control layer including: a first main groove in a non-display area of the substrate; a second main groove in the non-display area; and an auxiliary groove in the non-display area between the first main groove and the second main groove.

In an embodiment, a width of the auxiliary groove may be different from a width of the first main groove.

In an embodiment, the width of the auxiliary groove may be smaller than the width of the first main groove.

In an embodiment, a width of the first main groove and a width of the second main groove may be the same as each other.

In an embodiment, the display device may further include: a first encapsulation inorganic film on the flow control layer; an encapsulation organic film on the first encapsulation inorganic film; and a second encapsulation inorganic film on the encapsulation organic film.

In an embodiment, a residual film of the encapsulation organic film may be located in at least one of the first main groove, the second main groove, or the auxiliary groove of the flow control layer.

In an embodiment, the auxiliary groove may include a plurality of auxiliary grooves, and the residual film may include a plurality of residual films in the plurality of auxiliary grooves, respectively, the plurality of residual films being spaced from each other.

In an embodiment, a residual film located in at least one of the first main groove or the second main groove may have a thickness different from that of a residual film located in the auxiliary groove.

In an embodiment, the thickness of the residual film in the auxiliary groove may be greater than the thickness of the residual film in the at least one of the first main groove or the second main groove.

In an embodiment, a cavity surrounded by the second encapsulation inorganic film may be located in the auxiliary groove.

In an embodiment, the pixel defining film may include: a first pixel defining film; and a second pixel defining film on the first pixel defining film.

In an embodiment, the flow control layer may be located at the same layer as that of the first pixel defining film.

In an embodiment, the second pixel defining film may be further located between the flow control layer and the first encapsulation inorganic film.

In an embodiment, the auxiliary groove may include a plurality of auxiliary grooves, and the plurality of auxiliary grooves may have the same width as each other.

In an embodiment, an interval between adjacent auxiliary grooves from among the plurality of auxiliary grooves may be the same as an interval between other adjacent auxiliary grooves from among the plurality of auxiliary grooves.

In an embodiment, the auxiliary groove may include a plurality of auxiliary grooves, and widths of the plurality of auxiliary grooves may increase as they become farther from the center of the display area.

In an embodiment, the auxiliary groove may include a plurality of auxiliary grooves, and widths of the plurality of auxiliary grooves may decrease as they become farther from the center of the display area.

In an embodiment, the flow control layer may include: a base layer; and a plurality of protrusion patterns protruding from the base layer to define the first main groove, the second main groove, and the auxiliary groove.

According to one or more embodiments of the present disclosure, a method for fabricating a display device, includes: forming a flow control layer on a substrate, the flow control layer having a first main groove, a second main groove, and an auxiliary groove; forming a pixel defining film on the flow control layer; forming a first encapsulation inorganic film on the pixel defining film; forming an encapsulation organic film on the first encapsulation inorganic film; and forming a residual film in at least one of the first main groove, the second main groove, or the auxiliary groove by selectively removing a portion of the encapsulation organic film formed in a non-display area of the substrate.

According to one or more embodiments of the present disclosure, an electronic device includes: a display device including a screen. The display device includes: a substrate; a first electrode in a display area of the substrate; a light emitting layer on the first electrode; a pixel defining film on the light emitting layer; a second electrode on the pixel defining film; and a flow control layer including: a first main groove in a non-display area of the substrate; a second main groove in the non-display area; and an auxiliary groove between the first main groove and the second main groove in the non-display area.

According to some embodiments of the present disclosure, a flow of an encapsulation organic film may be controlled.

According to some embodiments of the present disclosure, at least one auxiliary groove may be formed between a first main groove and a second main groove of a flow control layer, and accordingly, a raw material of the encapsulation organic film may be prevented or substantially prevented from flowing to an edge of a substrate during a process of forming the encapsulation organic film. Accordingly, an encapsulation state of a display panel may be improved.

According to some embodiments of the present disclosure, a residual film disposed inside an auxiliary groove may not be connected to a residual film in another groove adjacent to the auxiliary groove, and may be maintained in a state of being spaced apart (e.g., separated) therefrom. Accordingly, even when a portion of the encapsulation organic film is exposed at an edge of the display panel, moisture from the outside may be prevented or substantially prevented from spreading to the encapsulation organic film disposed in a display area of the display panel.

According to some embodiments of the present disclosure, by checking a presence or an absence of a residual film disposed in the auxiliary groove, it may be possible to more easily determine how far the raw material for the encapsulation organic film has moved from a center of the display area. In addition, the auxiliary grooves may be used as a ruler to check an extent of a spread of the raw material of the encapsulation organic film.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is an exploded perspective view illustrating a display device according to an embodiment;

FIG. 2 is a block diagram illustrating a display device according to an embodiment;

FIG. 3 is an equivalent circuit diagram of a first pixel according to an embodiment;

FIG. 4 is a layout diagram illustrating an example of a display panel according to an embodiment;

FIG. 5 is a layout diagram illustrating a display area of FIG. 4 according to an embodiment;

FIG. 6 is a layout diagram illustrating a display area of FIG. 4 according to an embodiment;

FIG. 7 is a cross-sectional view illustrating an example of a display panel taken along the line I1-I1′ of FIG. 5;

FIG. 8 is an enlarged view of the area A of FIG. 4;

FIG. 9 is a cross-sectional view taken along the line I2-I2′ of FIG. 8;

FIG. 10 is a cross-sectional view of a display device according to an embodiment;

FIG. 11 is a cross-sectional view of a display device according to an embodiment;

FIGS. 12-14 are diagrams illustrating some processes of a method for fabricating a display device according to an embodiment;

FIG. 15 is a block diagram of an electronic device according to an embodiment;

FIG. 16 illustrates schematic diagrams of some electronic devices according to some embodiments;

FIG. 17 illustrates schematic diagrams of some electronic devices according to some embodiments; and

FIG. 18 illustrates schematic diagrams of some electronic devices according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. Further, when an element is described as a “first” element, this may not require or imply the presence of a “second” element or other elements. As used herein, the terms “first”, “second”, and the like may also be used to differentiate different categories or sets of elements. For example, the terms “first”, “second”, and the like may represent “a first-category (or a first-set)”, “a second-category (or a second-set)”, and the like, respectively.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure. ” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

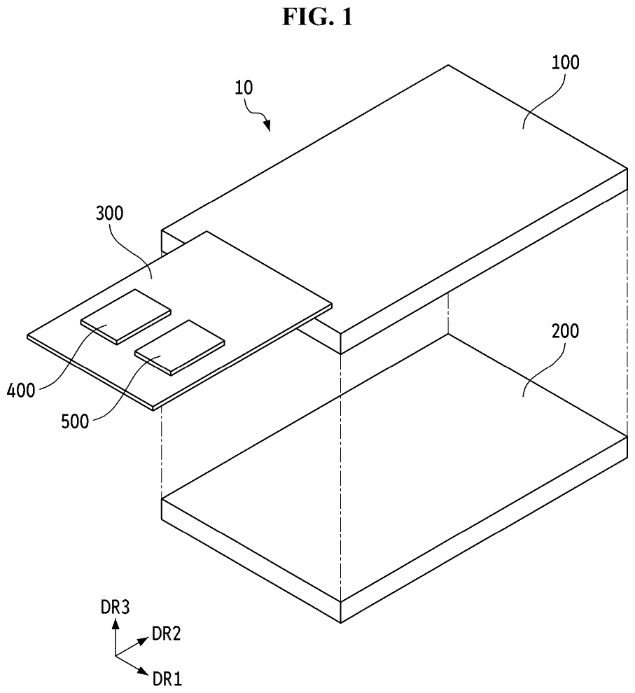

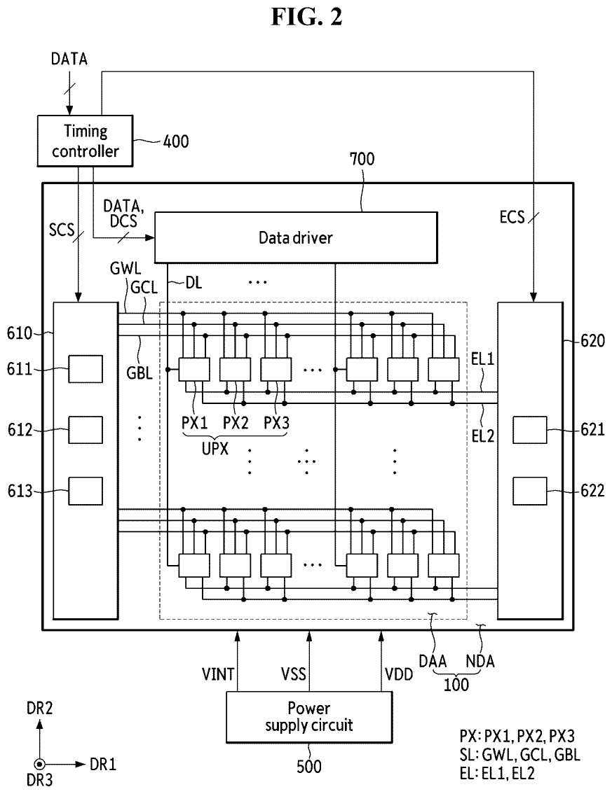

FIG. 1 is an exploded perspective view illustrating a display device according to an embodiment. FIG. 2 is a block diagram illustrating a display device according to an embodiment.

Referring to FIGS. 1 and 2, a display device 10 according to an embodiment is a device for displaying a moving image and/or a still image. The display device 10 according to an embodiment may be applied to or implemented as various suitable portable electronic devices, such as a mobile phone, a smartphone, a tablet personal computer, a mobile communication terminal, an electronic organizer, an electronic book, a portable multimedia player (PMP), a navigation system, an ultra mobile PC (UMPC), or the like. For example, the display device 10 according to an embodiment may be applied to or implemented as a display unit (e.g., a display screen) of various suitable electronic devices, for example, such a television, a laptop, a monitor, a billboard, or an Internet-of-Things (IoT) terminal or device. As another example, the display device 10 according to an embodiment may be applied to or implemented as a wearable electronic device, for example, such as a smart watch, a watch phone, a head mounted display (HMD) for implementing a virtual reality and/or an augmented reality, and the like.

The display device 10 according to an embodiment includes a display panel 100, a heat dissipation layer 200, a circuit board 300, a timing control circuit 400, and a power supply circuit 500.

The display panel 100 may have a planar shape similar to that of a quadrilateral shape. For example, the display panel 100 may have the planar shape similar to that of a quadrilateral shape having a short side extending in a first direction DR1, and a long side extending in a second direction DR2 crossing or intersecting the first direction DR1. In the display panel 100, a corner where a short side extending in the first direction DR1 and a long side extending in the second direction DR2 meet each other may be right-angled, or may be rounded with a suitable curvature (e.g., a predetermined curvature). However, the planar shape of the display panel 100 is not limited to the quadrilateral shape, and may be a suitable shape similar to another polygonal shape, a circular shape, or an elliptical shape. The planar shape of the display device 10 may conform to the planar shape of the display panel 100, but the present disclosure is not limited thereto.

The display panel 100 includes a display area DAA for displaying an image, and a non-display area NDA that does not display an image, as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being disposed along the second direction DR2. The plurality of data lines DL may extend in the second direction DR2, while being disposed along the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

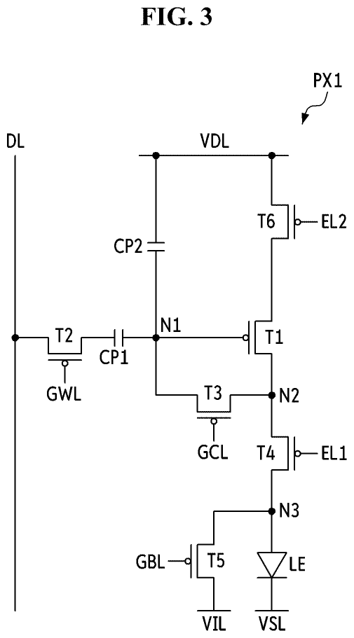

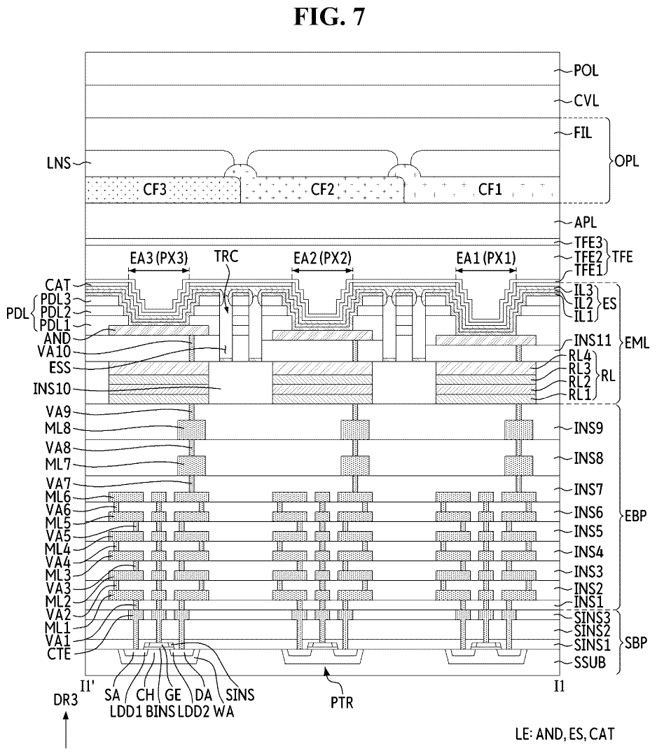

Each of a plurality of unit pixels UPX includes a plurality of pixels PX1, PX2, and PX3. Each of the plurality of pixels PX1, PX2, and PX3 may include a plurality of pixel transistors, as shown in FIG. 3, that may be formed through a semiconductor process, and a semiconductor substrate SSUB (e.g., see FIG. 7) may be disposed. For example, the plurality of pixel transistors and/or a plurality of data transistors of a data driver 700 may be formed of a complementary metal oxide semiconductor (CMOS).

Each of the plurality of pixels PX1, PX2, and PX3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of pixels PX1, PX2, and PX3 may receive a data voltage of the corresponding data line DL according to a write scan signal of the corresponding write scan line GWL, and may allow a light emitting element to emit light according to the data voltage.

The non-display area NDA may include a scan driver 610, an emission driver 620, and a data driver 700.

The scan driver 610 includes a plurality of scan transistors, and the emission driver 620 includes a plurality of light emitting transistors. The plurality of scan transistors and the plurality of light emitting transistors may be formed by a semiconductor process, and be formed at (e.g., in or on) a semiconductor substrate SSUB (e.g., see FIG. 7). For example, the plurality of scan transistors and the plurality of light emitting transistors may be formed as CMOSs. In FIG. 2, the scan driver 610 is illustrated as being disposed on the left side of the display area DAA and the emission driver 620 is illustrated as being disposed on the right side of the display area DAA, but the present disclosure is not limited thereto. For example, the scan drivers 610 and the emission drivers 620 may be disposed on both the left and right sides of the display area DAA.

The scan driver 610 may include a write scan signal output unit (e.g., a write scan signal output circuit) 611, a control scan signal output unit (e.g., a control scan signal output circuit) 612, and a bias scan signal output unit (e.g., a bias scan signal output circuit) 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400, and may sequentially output the write scan signals to the write scan lines GWL. The control scan signal output unit 612 may generate control scan signals according to the scan timing control signal SCS, and may sequentially output the control scan signals to the control scan lines GCL. The bias scan signal output unit 613 may generate bias scan signals according to the scan timing control signal SCS, and may sequentially output the bias scan signals to the bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS, and may sequentially output the first emission control signals to the first emission control lines EL1. The second emission control driver 622 may generate second emission control signals according to the emission timing control signal ECS, and may sequentially output the second emission control signals to the second emission control lines EL2.

The data driver 700 may include a plurality of data transistors. The plurality of data transistors may be formed by a semiconductor process, and may be formed at (e.g., in or on) a semiconductor substrate SSUB (e.g., see FIG. 7). For example, the plurality of data transistors may be formed as CMOSs.

The data driver 700 may receive digital video data DATA and a data timing control signal DCS from the timing control circuit 400. The data driver 700 converts the digital video data DATA into analog data voltages according to the data timing control signal DCS, and outputs the analog data voltages to the data lines DL. In this case, the pixels PX1, PX2, and PX3 may be selected by the write scan signals of the scan driver 610, and the data voltages may be supplied to the selected pixels PX1, PX2, and PX3.

The heat dissipation layer 200 may overlap with the display panel 100 in a third direction DR3, which is the thickness direction of the display panel 100. The heat dissipation layer 200 may be disposed on one surface, for example, such as a rear surface, of the display panel 100. The heat dissipation layer 200 serves to dissipate heat generated from the display panel 100. The heat dissipation layer 200 may include a metal layer made of graphite, silver (Ag), copper (Cu), or aluminum (Al), and having a high thermal conductivity.

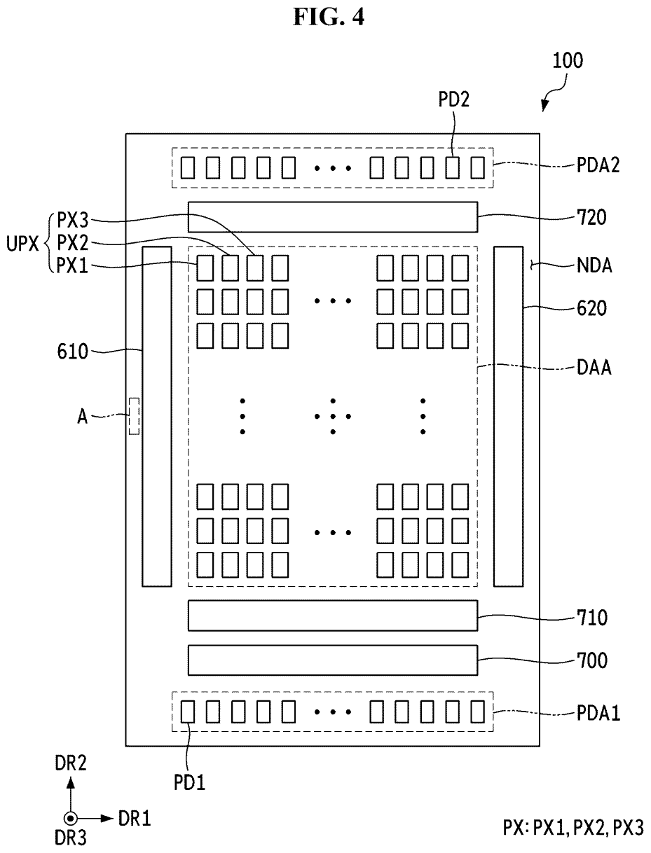

The circuit board 300 may be electrically connected to a plurality of first pads PD1 (e.g., see FIG. 4) of a first pad unit PDA1 of the display panel 100 using a conductive adhesive member, such as an anisotropic conductive film. The circuit board 300 may be a flexible printed circuit board or a flexible film having a flexible material.

In FIG. 1, the circuit board 300 is illustrated as being unbent, but the circuit board 300 may be bent. In this case, one end of the circuit board 300 may be disposed on the rear surface of the display panel 100 and/or a rear surface of the heat dissipation layer 200. The one end of the circuit board 300 may be an end opposite to another end of the circuit board 300 connected to the plurality of first pads PD1 (e.g., see FIG. 4) of the first pad unit PDA1 of the display panel 100 using the conductive adhesive member.

The timing control circuit 400 may receive digital video data and timing signals from the outside. The timing control circuit 400 may generate the scan timing control signal SCS, the emission timing control signal ECS, and the data timing control signal DCS, for controlling the display panel 100 according to the timing signals. The timing control circuit 400 may output the scan timing control signal SCS to the scan driver 610, and may output the emission timing control signal ECS to the emission driver 620. The timing control circuit 400 may output the digital video data and the data timing control signal DCS to the data driver 700.

The power supply circuit 500 may generate a plurality of panel power voltages according to an external source voltage. For example, the power supply circuit 500 may generate a common voltage VSS, a driving voltage VDD, and an initialization voltage VINT, and may supply the common voltage VSS, the driving voltage VDD, and the initialization voltage VINT to the display panel 100. The common voltage VSS, the driving voltage VDD, and the initialization voltage VINT will be described in more detail below with reference to FIG. 3.

Each of the timing control circuit 400 and the power supply circuit 500 may be formed as an integrated circuit (IC), and may be attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the common voltage VSS, the driving voltage VDD, and the initialization voltage VINT of the power supply circuit 500 may be supplied to the display panel 100 through the circuit board 300.

As another example, each of the timing control circuit 400 and the power supply circuit 500 may be disposed in the non-display area NDA of the display panel 100, similar to the scan driver 610, the emission driver 620, and the data driver 700. In this case, the timing control circuit 400 may include a plurality of timing transistors, and the power supply circuit 500 may include a plurality of power transistors. The plurality of timing transistors and the plurality of power transistors may be formed by a semiconductor process, and may be formed at (e.g., in or on) a semiconductor substrate SSUB (e.g., see FIG. 7). For example, the plurality of timing transistors and the plurality of power transistors may be formed as CMOSs. Each of the timing control circuit 400 and the power supply circuit 500 may be disposed between the data driver 700 and the first pad unit PDA1 (e.g., see FIG. 4).

FIG. 3 is an equivalent circuit diagram of a first pixel according to an embodiment.

Referring to FIG. 3, the first pixel PX1 may be connected to a write scan line GWL, a control scan line GCL, a bias scan line GBL, a first emission control line EL1, a second emission control line EL2, and a data line DL. In addition, the first pixel PX1 may be connected to a common voltage line VSL to which a common voltage VSS corresponding to a low potential voltage is applied, a driving voltage line VDL to which a driving voltage VDD corresponding to a high potential voltage is applied, and an initialization voltage line VIL to which an initialization voltage VINT is applied. In other words, the common voltage line VSL may be a low potential voltage line, the driving voltage line VDL may be a high potential voltage line, and the initialization voltage line VIL may be an initialization voltage line. In this case, the common voltage VSS may be a voltage lower than the initialization voltage VINT. The driving voltage VDD may be a voltage higher than the initialization voltage VINT.

The first pixel PX1 includes a plurality of transistors T1 to T6, a light emitting element LE, a first capacitor CP1, and a second capacitor CP2.

The light emitting element LE emits light according to a driving current flowing through a channel of a first transistor T1. An amount of light emitted from the light emitting element LE may be proportional to the driving current. The light emitting element LE may be disposed between a fourth transistor T4 and the common voltage line VSL. A first electrode of the light emitting element LE may be connected to a drain electrode of the fourth transistor T4, and a second electrode of the light emitting element LE may be connected to the common voltage line VSL. The first electrode of the light emitting element LE may be an anode electrode, and the second electrode of the light emitting element LE may be a cathode electrode. The light emitting element LE may be an organic light emitting diode including the first electrode, the second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, and in this case, the light emitting element LE may be a micro light emitting diode.

The first transistor T1 may be a driving transistor for controlling a source-drain current Ids (hereinafter referred to as the “driving current”) flowing between a source electrode and a drain electrode thereof according to a voltage applied to a gate electrode thereof. The first transistor T1 includes the gate electrode connected to a first node N1, the source electrode connected to a drain electrode of a sixth transistor T6, and the drain electrode connected to a second node N2.

A second transistor T2 may be disposed between one electrode of the first capacitor CP1 and the data line DL. The second transistor T2 is turned on by a write scan signal of the write scan line GWL to connect the one electrode of the first capacitor CP1 to the data line DL. As such, a data voltage of the data line DL may be applied to one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by a write control signal of the control scan line GCL to connect the first node N1 to the second node N2. As such, the gate electrode and the drain electrode of the first transistor T1 may be connected to each other, and thus, the first transistor T1 may operate like a diode. In other words, the third transistor T3 may be diode-connected to the first transistor T1. The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. As such, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be disposed between the third node N3 and the initialization voltage line VIL. The fifth transistor T5 is turned on by a bias scan signal of the bias scan line GBL to connect the third node N3 to the initialization voltage line VIL. As such, the initialization voltage VINT of the initialization voltage line VIL may be applied to the first electrode of the light emitting element LE. The fifth transistor T5 includes a gate electrode connected to the bias scan line GBL, a source electrode connected to the third node N3, and a drain electrode connected to the initialization voltage line VIL.

The sixth transistor T6 may be disposed between the source electrode of the first transistor T1 and the driving voltage line VDL. The sixth transistor T6 is turned on by a second emission control signal of the second emission control line EL2 to connect the source electrode of the first transistor T1 to the driving voltage line VDL. As such, the driving voltage VDD of the driving voltage line VDL may be applied to the source electrode of the first transistor T1. The sixth transistor T6 includes a gate electrode connected to the second emission control line EL2, a source electrode connected to the driving voltage line VDL, and the drain electrode connected to the source electrode of the first transistor T1.

The first capacitor CP1 is formed between the first node N1 and the drain electrode of the second transistor T2. The first capacitor CP1 includes the one electrode connected to the drain electrode of the second transistor T2, and another electrode connected to the first node N1.

The second capacitor CP2 is formed between the gate electrode of the first transistor T1 and the driving voltage line VDL. The second capacitor CP2 includes one electrode connected to the gate electrode of the first transistor T1, and another electrode connected to the driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. As another example, some of the first to sixth transistors T1 to T6 may be P-type MOSFETs, and others of the first to sixth transistors T1 to T6 may be N-type MOSFETs.

In FIG. 3, the first pixel PX1 is illustrated as including six transistors T1 to T6 and two capacitors CP1 and CP2, but the equivalent circuit diagram of the first pixel PX1 is not limited thereto. For example, the numbers of transistors and capacitors of the first pixel PX1 are not limited to those illustrated in FIG. 3.

In addition, an equivalent circuit diagram of a second pixel PX2 and an equivalent circuit diagram of a third pixel PX3 may be the same or substantially the same as the equivalent circuit diagram of the first pixel PX1 described above with reference to FIG. 3. Therefore, redundant description thereof may not be repeated.

FIG. 4 is a layout diagram illustrating an example of a display panel according to an embodiment.

Referring to FIG. 4, the display area DAA of the display panel 100 according to an embodiment includes a plurality of pixels PX arranged in a matrix form. The non-display area NDA of the display panel 100 according to an embodiment includes a scan driver 610, an emission driver 620, a data driver 700, a first distribution circuit 710, a second distribution circuit 720, a first pad unit (e.g., a first pad area) PDA1, and a second pad unit (e.g., a second pad area) PDA2.

The scan driver 610 may be disposed on a first side of the display area DAA, and the emission driver 620 may be disposed on a second side of the display area DAA. For example, the scan driver 610 may be disposed on one side of the display area DAA in the first direction DR1, and the emission driver 620 may be disposed on the other side of the display area DAA in the first direction DR1. In other words, the scan driver 610 may be disposed on the left side of the display area DAA, and the emission driver 620 may be disposed on the right side of the display area DAA. However, the present disclosure is not limited thereto, and the scan drivers 610 and the emission drivers 620 may be disposed on both the first and second sides of the display area DAA.

The first pad unit PDA1 may include a plurality of first pads PD1 connected to pads or bumps of the circuit board 300 through a conductive adhesive member. The first pad unit PDA1 may be disposed on a third side of the display area DAA. For example, the first pad unit PDA1 may be disposed on one side of the display area DAA in the second direction DR2.

The first pad unit PDA1 may be disposed outside the data driver 700 in the second direction DR2. In other words, the first pad unit PDA1 may be disposed closer to an edge of the display panel 100 than the data driver 700 is.

The second pad unit PDA2 may include a plurality of second pads PD2 corresponding to inspection pads to inspect whether or not the display panel 100 operates normally. The plurality of second pads PD2 may be connected to a jig or a probe pin, or may be connected to a circuit board for inspection in an inspection process. The circuit board for inspection may be a printed circuit board made of a rigid material, or may be a flexible printed circuit board made of a flexible material.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (where P is a positive integer of 2 or more), and as such, the number of first pads PD1 may be reduced. The first distribution circuit 710 may be disposed on the third side of the display area DAA of the display panel 100. For example, the first distribution circuit 710 may be disposed on one side of the display area DAA in the second direction DR2. In other words, the first distribution circuit 710 may be disposed on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on a fourth side of the display area DAA of the display panel 100. For example, the second distribution circuit 720 may be disposed on the other side of the display area DAA in the second direction DR2. In other words, the second distribution circuit 720 may be disposed on the upper side of the display area DAA.

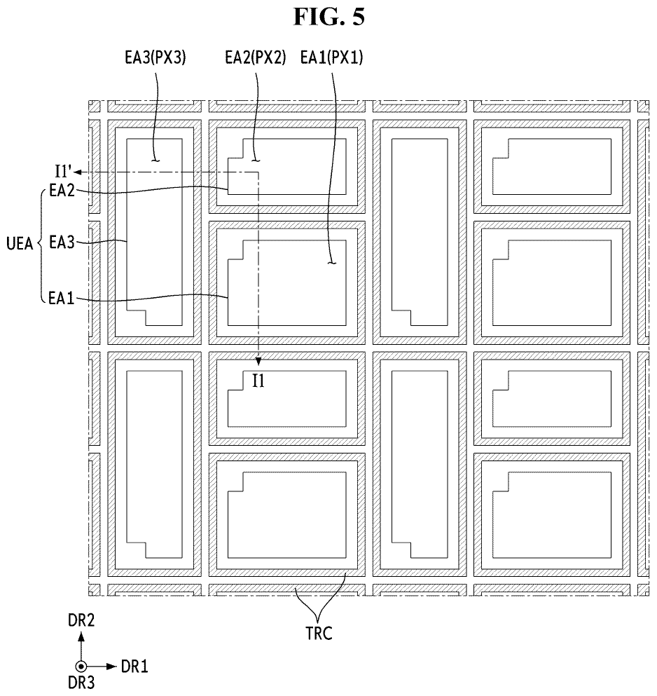

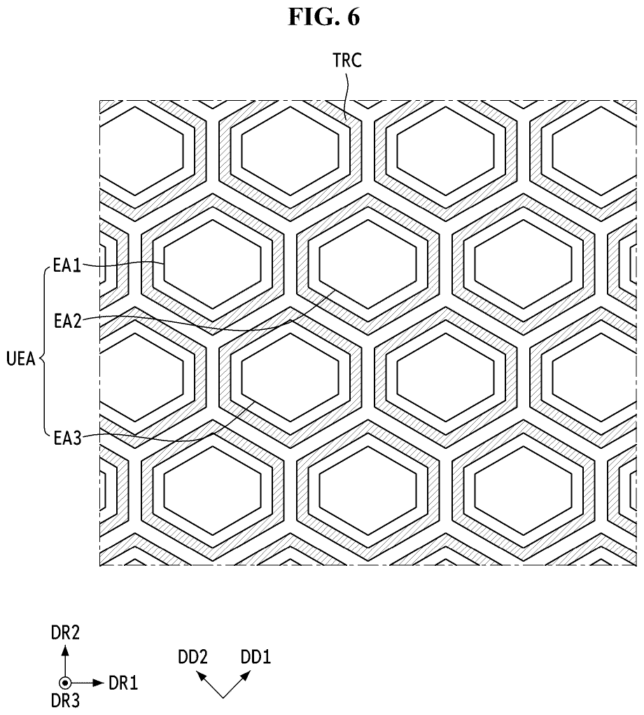

FIG. 5 is a layout diagram illustrating a display area of FIG. 4 according to an embodiment. FIG. 6 is a layout diagram illustrating a display area of FIG. 4 according to an embodiment.

Referring to FIG. 5, each of the plurality of unit pixels UPX includes a corresponding first emission area EA1 that is an emission area of the first pixel PX1, a corresponding second emission area EA2 that is an emission area of the second pixel PX2, and a corresponding third emission area EA3 that is an emission area of the third pixel PX3. In other words, the unit pixel UPX may include a unit emission area UEA, and the unit emission area UEA may include the above-described first emission area EA1, the second emission area EA2, and the third emission area EA3.

Referring to FIG. 6, each of the plurality of unit pixels UPX includes a corresponding first emission area EA1 that is an emission area of the first pixel PX1, a corresponding second emission area EA2 that is an emission area of the second pixel PX2, and a corresponding third emission area EA3 that is an emission area of the third pixel PX3.

Referring to FIGS. 5 and 6, each of the first emission area EA1, the second emission area EA2, and the third emission area EA3 may have a polygonal shape, a circular shape, an elliptical shape, or an irregular shape in a plan view.

A maximum length of the third emission area EA3 in the first direction DR1 may be smaller than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be the same or substantially the same as each other.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be smaller than the maximum length of the third emission area EA3 in the second direction DR2.

Each of the first emission area EA1, the second emission area EA2, and the third emission area EA3 may have a hexagonal shape including six straight lines, in a plan view, as illustrated in FIG. 6, but the present disclosure is not limited thereto. Each of the first emission area EA1, the second emission area EA2, and the third emission area EA3 may have polygonal shapes other than the hexagonal shape, a circular shape, an elliptical shape, or an irregular shape in a plan view.

As illustrated in FIG. 5, in each of the plurality of unit pixels UPX, the first emission area EA1 and the second emission area EA2 may neighbor to each other in the second direction DR2. In addition, the first emission area EA1 and the third emission area EA3 may neighbor to each other in the first direction DR1. In addition, the second emission area EA2 and the third emission area EA3 may neighbor to each other in the first direction DR1. An area of the first emission area EA1, an area of the second emission area EA2, and an area of the third emission area EA3 may be different from each other.

As another example, as illustrated in FIG. 6, the first emission area EA1 and the second emission area EA2 may neighbor to each other in the first direction DR1. The second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2, and may refer to a direction inclined by 45° with respect to the first direction DR1 and the second direction DR2. The second diagonal direction DD2 may be a direction orthogonal to or substantially orthogonal to the first diagonal direction DD1.

The first emission area EA1 may emit light of a first color, the second emission area EA2 may emit light of a second color, and the third emission area EA3 may emit light of a third color. The light of the first color may be light of a blue wavelength band, the light of the second color may be light of a green wavelength band, and the light of the third color may be light of a red wavelength band. For example, the blue wavelength band may indicate that a main peak wavelength of the light is included in a wavelength band of approximately 370 nm to 460 nm, the green wavelength band may indicate that a main peak wavelength of the light is included in a wavelength band of approximately 480 nm to 560 nm, and the red wavelength band may indicate that a main peak wavelength of the light is included in a wavelength band of approximately 600 nm to 750 nm.

In FIGS. 5 and 6, each of the plurality of unit pixels UPX is illustrated as including three emission areas EA1, EA2, and EA3, but the present disclosure is not limited thereto. In other words, each of the plurality of unit pixels UPX may include four emission areas.

In addition, an arrangement of the emission areas of the plurality of unit pixels UPX is not limited to those illustrated in FIGS. 5 and 6. For example, the emission areas of the plurality of unit pixels UPX may be disposed in a stripe structure in which the emission areas are arranged along the first direction DR1, a diamond structure (e.g., a PENTILE® structure, PENTILE® being a duly registered trademark of Samsung Display Co., Ltd.) in which the emission areas have a diamond arrangement, or a hexagonal structure in which emission areas having a hexagonal shape in a plan view are arranged like that illustrated in FIG. 6.

FIG. 7 is a cross-sectional view illustrating an example of a display panel taken along the line I1-I1′ of FIG. 5.

Referring to FIG. 7, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described above with reference to FIG. 3.

The semiconductor substrate SSUB may be a silicon substrate, a germanium substrate, or a silicon-germanium substrate. The semiconductor substrate SSUB may be doped with first-type impurities. A plurality of well regions WA may be disposed in an upper surface of the semiconductor substrate SSUB. The plurality of well regions WA may be regions doped with second-type impurities. The second-type impurities may be different from the first-type impurities. For example, when the first-type impurities are p-type impurities, the second-type impurities may be n-type impurities. As another example, when the first-type impurities are n-type impurities, the second-type impurities may be p-type impurities.

Each of the plurality of well regions WA includes a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region that is doped with the first-type impurities. The gate electrode GE of the pixel transistor PTR may overlap with the well region WA in the third direction DR3. The channel region CH may overlap with the gate electrode GE in the third direction DR3. The source region SA may be disposed on one side of the gate electrode GE, and the drain region DA may be disposed on another side (e.g., an opposite side) of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than that of the source region SA due to the bottom insulating film BINS. The second low-concentration impurity region LDD2 may be a region having a lower impurity concentration than that of the drain region DA due to the bottom insulating film BINS. A distance between the source region SA and the drain region DA may be increased by the first low-concentration impurity region LDD1 and the second low-concentration impurity region LDD2. Therefore, a length of the channel region CH of each of the pixel transistors PTR may be increased, and thus, a punch-through phenomena and a hot carrier phenomena that may be caused by a shorter channel may be prevented or substantially prevented.

A first semiconductor insulating film SINS1 may be disposed on the semiconductor substrate SSUB. The first semiconductor insulating film SINS1 may be formed as a silicon carbonitride (SiCN) or silicon oxide (SiOₓ)-based inorganic film, but the present disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but the present disclosure is not limited thereto.

The plurality of contact terminals CTE may be disposed on the second semiconductor insulating film SINS2. Each of the plurality of contact terminals CTE may be connected to any one of the gate electrode GE, the source region SA, or the drain region DA of a corresponding one of the pixel transistors PTR through a hole penetrating through the first semiconductor insulating film SINS1 and the second semiconductor insulating film SINS2. Each of the plurality of contact terminals CTE may be made of any one of copper (Cu), aluminum (Al), tungsten (W), molybdenum (Mo), chromium (Cr), gold (Au), titanium (Ti), nickel (Ni), neodymium (Nd), or suitable alloys thereof.

A third semiconductor insulating film SINS3 may be disposed on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but the present disclosure is not limited thereto.

In another embodiment, the semiconductor substrate SSUB may be replaced with a glass substrate, or a polymer resin substrate such as a polyimide substrate. In this case, thin film transistors may be disposed on the glass substrate or the polymer resin substrate. The glass substrate may be a rigid substrate that may not be bent, and the polymer resin substrate may be a flexible substrate that may be bent or curved.

The light emitting element backplane EBP includes a plurality of conductive layers ML1 to ML8, a plurality of vias VA1 to VA9, and a plurality of insulating films INS1 to INS9. The plurality of insulating films INS1 to INS9 may be disposed between first to eighth conductive layers ML1 to ML8.

The first to eighth conductive layers ML1 to ML8 serve to implement a circuit of the first pixel PX1 (e.g., see FIG. 3) by connecting the plurality of contact terminals CTE exposed from the semiconductor backplane SBP to one another. For example, only the first to sixth transistors T1 to T6 may be formed in the semiconductor backplane SBP, and the connection between the first to sixth transistors T1 to T6 and the formation of the first capacitor CP1 and the second capacitor CP2 may be performed through the first to eighth conductive layers ML1 to ML8. In addition, the connection between a drain region corresponding to a drain electrode of the fourth transistor T4, a source region corresponding to a source electrode of the fifth transistor T5, and the first electrode of a light emitting element LE may also be performed through the first to eighth conductive layers ML1 to ML8.

A first insulating film INS1 may be disposed on the semiconductor backplane SBP. Each of first vias VA1 may penetrate through the first insulating film INS1 to be connected to a corresponding contact terminal CTE exposed from the semiconductor backplane SBP. Each of the first conductive layers ML1 may be disposed on the first insulating film INS1, and be connected to a corresponding first via VA1.

A second insulating film INS2 may be disposed on the first insulating film INS1 and the first conductive layers ML1. Each of second vias VA2 may penetrate through the second insulating film INS2 to be connected to a corresponding exposed first conductive layer ML1. Each of the second conductive layers ML2 may be disposed on the second insulating film INS2, and may be connected to a corresponding second via VA2.

A third insulating film INS3 may be disposed on the second insulating film INS2 and the second conductive layers ML2. Each of third vias VA3 may penetrate through the third insulating film INS3 to be connected to a corresponding exposed second conductive layer ML2. Each of the third conductive layers ML3 may be disposed on the third insulating film INS3, and may be connected to a corresponding third via VA3.

A fourth insulating film INS4 may be disposed on the third insulating film INS3 and the third conductive layers ML3. Each of fourth vias VA4 may penetrate through the fourth insulating film INS4 to be connected to a corresponding exposed third conductive layer ML3. Each of the fourth conductive layers ML4 may be disposed on the fourth insulating film INS4, and may be connected to a corresponding fourth via VA4.

A fifth insulating film INS5 may be disposed on the fourth insulating film INS4 and the fourth conductive layers ML4. Each of fifth vias VA5 may penetrate through the fifth insulating film INS5 to be connected to a corresponding exposed fourth conductive layer ML4. Each of the fifth conductive layers ML5 may be disposed on the fifth insulating film INS5, and may be connected to a corresponding fifth via VA5.

A sixth insulating film INS6 may be disposed on the fifth insulating film INS5 and the fifth conductive layers ML5. Each of sixth vias VA6 may penetrate through the sixth insulating film INS6 to be connected to a corresponding exposed fifth conductive layer ML5. Each of the sixth conductive layers ML6 may be disposed on the sixth insulating film INS6, and may be connected to a corresponding sixth via VA6.

A seventh insulating film INS7 may be disposed on the sixth insulating film INS6 and the sixth conductive layers ML6. Each of seventh vias VA7 may penetrate through the seventh insulating film INS7 to be connected to a corresponding exposed sixth conductive layer ML6. Each of the seventh conductive layers ML7 may be disposed on the seventh insulating film INS7, and may be connected to a corresponding seventh via VA7.

An eighth insulating film INS8 may be disposed on the seventh insulating film INS7 and the seventh conductive layers ML7. Each of eighth vias VA8 may penetrate through the eighth insulating film INS8 to be connected to a corresponding exposed seventh conductive layer ML7. Each of the eighth conductive layers ML8 may be disposed on the eighth insulating film INS8, and may be connected to a corresponding eighth via VA8.

The first to eighth conductive layers ML1 to ML8 and the first to eighth vias VA1 to VA8 may be made of the same or substantially the same material as each other. Each of the first to eighth conductive layers ML1 to ML8 and the first to eighth vias VA1 to VA8 may be made of any one of copper (Cu), aluminum (Al), tungsten (W), molybdenum (Mo), chromium (Cr), gold (Au), titanium (Ti), nickel (Ni), neodymium (Nd), or suitable alloys thereof. The first to eighth vias VA1 to VA8 may be made of the same or substantially the same material as each other. The first to eighth insulating films INS1 to INS8 may be formed as silicon oxide (SiOₓ)-based inorganic films, but the present disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be the same or substantially the same as each other. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the thickness of the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be the same or substantially the same as each other. For example, each of the thickness of the seventh conductive layer ML7 and the thickness of the eighth conductive layer ML8 may be approximately 9000 Å. Each of the thickness of the seventh via VA7 and the thickness of the eighth via VA8 may be approximately 6000 Å.

A ninth insulating film INS9 may be disposed on the eighth insulating film INS8 and the eighth conductive layer ML8. The ninth insulating film INS9 may be formed as a silicon oxide (SiOₓ)-based inorganic film, but the present disclosure is not limited thereto.

Each of ninth vias VA9 may penetrate through the ninth insulating film INS9 to be connected to a corresponding exposed eighth conductive layer ML8. Each of the ninth vias VA9 may be made of any one of copper (Cu), aluminum (Al), tungsten (W), molybdenum (Mo), chromium (Cr), gold (Au), titanium (Ti), nickel (Ni), neodymium (Nd), or suitable alloys thereof. A thickness of the ninth via VA9 may be approximately 16500 Å.

The display element layer EML may be disposed on the light emitting element backplane EBP. The display element layer EML may include a reflective electrode layer RL, tenth and eleventh insulating films INS10 and INS11, tenth vias VA10, light emitting elements LE, a pixel defining film PDL, and a plurality of trenches TRC. Each of the light emitting elements LE may include a first electrode AND, a light emitting stack ES, and a second electrode CAT.

The reflective electrode layer RL may be disposed on the ninth insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 7.

Each of the first reflective electrodes RL1 may be disposed on the ninth insulating film INS9, and may be connected to a corresponding ninth via VA9. Each of the first reflective electrodes RL1 may be made of any one of copper (Cu), aluminum (Al), tungsten (W), molybdenum (Mo), chromium (Cr), gold (Au), titanium (Ti), nickel (Ni), neodymium (Nd), or suitable alloys thereof. For example, each of the first reflective electrodes RL1 may include titanium nitride (TiN).

Each of the second reflective electrodes RL2 may be disposed on a corresponding first reflective electrode RL1. Each of the second reflective electrodes RL2 may be made of any one of copper (Cu), aluminum (Al), tungsten (W), molybdenum (Mo), chromium (Cr), gold (Au), titanium (Ti), nickel (Ni), neodymium (Nd), or suitable alloys thereof. For example, each of the second reflective electrodes RL2 may include aluminum (Al).

Each of the third reflective electrodes RL3 may be disposed on a corresponding second reflective electrode RL2. Each of the third reflective electrodes RL3 may be made of any one of copper (Cu), aluminum (Al), tungsten (W), molybdenum (Mo), chromium (Cr), gold (Au), titanium (Ti), nickel (Ni), neodymium (Nd), or suitable alloys thereof. For example, each of the third reflective electrodes RL3 may include titanium nitride (TiN).

Each of the fourth reflective electrodes RL4 may be disposed on a corresponding third reflective electrode RL3. Each of the fourth reflective electrodes RL4 may be made of any one of copper (Cu), aluminum (Al), tungsten (W), molybdenum (Mo), chromium (Cr), gold (Au), titanium (Ti), nickel (Ni), neodymium (Nd), or suitable alloys thereof. For example, each of the fourth reflective electrodes RL4 may include titanium (Ti).

Because the second reflective electrodes RL2 are electrodes substantially reflecting light from the light emitting elements LE, a thickness of the second reflective electrode RL2 may be greater than a thickness of the first reflective electrode RL1, a thickness of the third reflective electrode RL3, and a thickness of the fourth reflective electrode RL4. For example, the thicknesses of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be disposed on the reflective electrode layer RL in the third pixel PX3. The tenth insulating film INS10 may be formed as a silicon oxide (SiOₓ)-based inorganic film, but the present disclosure is not limited thereto.

The eleventh insulating film INS11 may be disposed on the tenth insulating film INS10 and the reflective electrode layer RL. The eleventh insulating film INS11 may be formed as a silicon oxide (SiOₓ)-based inorganic film, but the present disclosure is not limited thereto. The tenth insulating film INS10 and the eleventh insulating film INS11 may be optical auxiliary layers through which light reflected by the reflective electrode layer RL among light emitted from the light emitting elements LE pass.

In order to adjust a resonance distance of the light emitted from the light emitting elements LE in at least one of the first pixel PX1, the second pixel PX2, or the third pixel PX3, the tenth insulating film INS10 and the eleventh insulating film INS11 may not be disposed below the first electrode AND of the first pixel PX1. The first electrode AND of the first pixel PX1 may be directly disposed on the reflective electrode layer RL. The eleventh insulating film INS11 may be disposed below the first electrode AND of the second pixel PX2. The tenth insulating film INS10 and the eleventh insulating film INS11 may be disposed below the first electrode AND of the third pixel PX3.

Accordingly, a distance between the first electrode AND and the reflective electrode layer RL may be different in each of the first pixel PX1, the second pixel PX2, and the third pixel PX3. In other words, in order to adjust a distance from the reflective electrode layer RL to the second electrode CAT according to a main wavelength of light emitted from each of the first pixel PX1, the second pixel PX2, and third pixel PX3, the presence or the absence of the tenth insulating film INS10 and the eleventh insulating film INS11 may be variously modified in each of the first pixel PX1, the second pixel PX2, and the third pixel PX3. For example, in FIG. 7, a distance between the first electrode AND and the reflective electrode layer RL in the third pixel PX3 is illustrated as being greater than a distance between the first electrode AND and the reflective electrode layer RL in the second pixel PX2 and a distance between the first electrode AND and the reflective electrode layer RL in the first pixel PX1, and the distance between the first electrode AND and the reflective electrode layer RL in the second pixel PX2 is illustrated as being greater than the distance between the first electrode AND and the reflective electrode layer RL in the first pixel PX1, but the present disclosure is not limited thereto.

In addition, while the tenth insulating film INS10 and the eleventh insulating film INS11 are illustrated in FIG. 7 according to an embodiment of the present disclosure, in some embodiments, a twelfth insulating film that is disposed below the first electrode AND of the first pixel PX1 may be further added. In this case, the eleventh insulating film INS11 and the twelfth insulating film may be disposed below the first electrode AND of the second pixel PX2, and the tenth insulating film INS10, the eleventh insulating film INS11, and the twelfth insulating film may be disposed below the first electrode AND of the third pixel PX3.

Each of the tenth vias VA10 may penetrate through the tenth insulating film INS10 and/or the eleventh insulating film INS11 in the second pixel PX2 and the third pixel PX3 to be connected to a corresponding exposed fourth reflective electrode RL4. Each of the tenth vias VA10 may be made of any one of copper (Cu), aluminum (Al), tungsten (W), molybdenum (Mo), chromium (Cr), gold (Au), titanium (Ti), nickel (Ni), neodymium (Nd), or suitable alloys thereof. A thickness of the tenth via VA10 in the second pixel PX2 may be smaller than a thickness of the tenth via VA10 in the third pixel PX3.

The first electrode AND of each of the light emitting elements LE may be disposed on the tenth insulating film INS10, and may be connected to a corresponding tenth via VA10. The first electrode AND of each of the light emitting elements LE may be connected to the drain region DA or the source region SA of a corresponding pixel transistor PTR through the corresponding tenth via VA10, the corresponding first to fourth reflective electrodes RL1 to RL4, the corresponding first to ninth vias VA1 to VA9, the corresponding first to eighth conductive layers ML1 to ML8, and the corresponding contact terminal CTE. The first electrode AND of each of the light emitting elements LE may be made of any one of copper (Cu), aluminum (Al), tungsten (W), molybdenum (Mo), chromium (Cr), gold (Au), titanium (Ti), nickel (Ni), neodymium (Nd), or suitable alloys thereof. For example, the first electrode AND of each of the light emitting elements LE may be made of titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the first emission areas EA1, the second emission areas EA2, and the third emission areas EA3.

The first emission area EA1 may be defined as an area where the first electrode AND, the light emitting stack ES, and the second electrode CAT are sequentially stacked in the first pixel PX1 to emit light. The second emission area EA2 may be defined as an area where the first electrode AND, the light emitting stack ES, and the second electrode CAT are sequentially stacked in the second pixel PX2 to emit light. The third emission area EA3 may be defined as an area where the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but the present disclosure is not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first encapsulation inorganic film TFE1 may be disconnected due to a step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, in order to prevent or substantially prevent the first encapsulation inorganic film TFE1 from being disconnected due to the step coverage, the first pixel defining film PDL1, the second pixel defining film PDL2, and the third pixel defining film PDL3 may have a cross-sectional structure having a step having a staircase shape. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length, in the horizontal direction, of the first pixel defining film PDL1 defined by the first direction DR1 and the second direction DR2.

Each of the plurality of trenches TRC may penetrate through the first pixel defining film PDL1, the second pixel defining film PDL2, and the third pixel defining film PDL3. In addition, each of the plurality of trenches TRC may penetrate through the eleventh insulating film INS11. In each of the plurality of trenches TRC, the tenth insulating film INS10 may have a shape in which a portion thereof is trenched.

At least one trench TRC may be disposed between the pixels PX1, PX2, and PX3 neighboring to each other. In FIG. 7, two trenches TRC are illustrated as being disposed between the pixels PX1, PX2, and PX3 neighboring to each other, but the present disclosure is not limited thereto.

The light emitting stack ES may include a plurality of stack layers. In FIG. 7, the light emitting stack ES is illustrated as having a three-tandem structure including a first stack layer IL1, a second stack layer IL2, and a third stack layer IL3, but the present disclosure is not limited thereto. For example, the light emitting stack ES may have a two-tandem structure including two stack layers.

In the three-tandem structure, the light emitting stack ES may have a tandem structure including a plurality of stack layers IL1, IL2, and IL3 emitting different light (e.g., different colored light) from each other. For example, the light emitting stack ES may include a first stack layer IL1 for emitting light of a first color, a second stack layer IL2 for emitting light of a third color, and a third stack layer IL3 for emitting light of a second color. The first stack layer IL1, the second stack layer IL2, and the third stack layer IL3 may be sequentially stacked.

The first stack layer IL1 may have a structure in which a first hole transporting layer, a first organic light emitting layer for emitting light of the first color, and a first electron transporting layer are sequentially stacked. The second stack layer IL2 may have a structure in which a second hole transporting layer, a second organic light emitting layer for emitting light of the third color, and a second electron transporting layer are sequentially stacked. The third stack layer IL3 may have a structure in which a third hole transporting layer, a third organic light for emitting layer emitting light of the second color, and a third electron transporting layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer for supplying electrons to the first stack layer IL1, and a P-type charge generation layer for supplying holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer for supplying electrons to the second stack layer IL2, and a P-type charge generation layer for supplying holes to the third stack layer IL3.

The first stack layer IL1 may be disposed on the first electrodes AND and the pixel defining film PDL, and may be disposed on a bottom surface of each of the trenches TRC. Due to the trenches TRC, the first stack layer IL1 may be disconnected between the pixels PX1, PX2, and PX3 neighboring each other. The second stack layer IL2 may be disposed on the first stack layer IL1. Due to the trenches TRC, the second stack layer IL2 may be disconnected between the pixels PX1, PX2, and PX3 neighboring each other. A cavity ESS or an empty space may be disposed between the first stack layer IL1 and the second stack layer IL2. The third stack layer IL3 may be disposed on the second stack layer IL2. The third stack layer IL3 may not be disconnected by the trenches TRC, and may be disposed to cover the second stack layer IL2 in each of the trenches TRC. In other words, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 neighboring each other. In addition, in the two-tandem structure, each of the plurality of trenches TRC may be a structure for disconnecting a charge generation layer disposed between a lower intermediate layer and an upper intermediate layer and the lower intermediate layer.

In order to stably disconnect the first and second stack layers IL1 and IL2 of the display element layer EML between the pixels PX1, PX2, and PX3 neighboring each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second intermediate layers IL1 and IL2 of the display element layer EML between the pixels PX1, PX2, and PX3 neighboring each other, other suitable structures may exist instead of the trenches TRC. For example, instead of the trenches TRC, partition walls having a reverse tapered shape may be disposed on the pixel defining film PDL.

The number of stack layers IL1, IL2, and IL3 for emitting the different light is not limited to that illustrated in FIG. 7. For example, the light emitting stack ES may include two intermediate layers. In this case, any one of the two intermediate layers may be the same or substantially the same as the first stack layer IL1, and the other of the two intermediate layers may include a second hole transporting layer, a second organic light emitting layer, a third organic light emitting layer, and a second electron transporting layer. In this case, a charge generation layer for supplying electrons to any one intermediate layer and supplying charges to the other intermediate layer may be disposed between the two intermediate layers.

In FIG. 7, the first to third stack layers IL1, IL2, and IL3 are illustrated as being all disposed in the first emission area EA1, the second emission area EA2, and the third emission area EA3, but the present disclosure is not limited thereto. For example, the first stack layer IL1 may be disposed in the first emission area EA1, and may not be disposed in the second emission area EA2 and the third emission area EA3. In addition, the second stack layer IL2 may be disposed in the second emission area EA2, and may not be disposed in the first emission area EA1 and the third emission area EA3. In addition, the third stack layer IL3 may be disposed in the third emission area EA3, and may not be disposed on the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO), such as ITO or IZO, that may transmit light, or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic film TFE1 or TFE3 and at least one organic film TFE2 in order to prevent or substantially prevent oxygen and/or moisture from permeating into the display element layer EML. For example, the encapsulation layer TFE may include a first encapsulation inorganic film TFE1, a second encapsulation inorganic film TFE3, and an encapsulation organic film TFE2. The encapsulation organic film TFE2 may be disposed between the first encapsulation inorganic film TFE1 and the second encapsulation inorganic film TFE3.

The first encapsulation inorganic film TFE1 may be disposed on the second electrode CAT. The first encapsulation inorganic film TFE1 may be formed as multiple films in which one or more inorganic films of a silicon nitride (SiNₓ) layer, a silicon oxynitride (SiON) layer, and/or a silicon oxide (SiOₓ) layer are alternately stacked. The first encapsulation inorganic film TFE1 may be formed by a chemical vapor deposition (CVD) process.

The encapsulation organic film TFE2 may be disposed on the first encapsulation inorganic film TFE1. The encapsulation organic film TFE2 may be an organic film made of an acrylic resin, an epoxy resin, a phenolic resin, a polyamide resin, a polyimide resin, or the like. The encapsulation organic film TFE2 may include a monomer.

The second encapsulation inorganic film TFE3 may be disposed on the encapsulation organic film TFE2. The second encapsulation inorganic film TFE3 may be formed as a titanium oxide (TiOₓ) layer or an aluminum oxide (AlOₓ) layer, but the present disclosure is not limited thereto. The second encapsulation inorganic film TFE3 may be formed by an atomic layer deposition (ALD) process. A thickness of the second encapsulation inorganic film TFE3 may be smaller than a thickness of the first encapsulation inorganic film TFE1.

An organic film APL may be a layer for increasing an interfacial adhesive strength between the encapsulation layer TFE and the optical layer OPL. The organic film APL may be an organic film made of an acrylic resin, an epoxy resin, a phenolic resin, a polyamide resin, a polyimide resin, or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the organic film APL.

The first color filter CF1 may overlap with the first emission area EA1 of the first pixel PX1. The first color filter CF1 may transmit light of the first color, or in other words, light of the blue wavelength band, therethrough. The blue wavelength band may be approximately 370 nm to 460 nm. Therefore, the first color filter CF1 may transmit light of the first color among light emitted from the first emission area EA1 therethrough.

The second color filter CF2 may overlap with the second emission area EA2 of the second pixel PX2. The second color filter CF2 may transmit light of the second color, or in other words, light of the green wavelength band, therethrough. The green wavelength band may be approximately 480 nm to 560 nm. Therefore, the second color filter CF2 may transmit light of the second color among light emitted from the second emission area EA2 therethrough.

The third color filter CF3 may overlap with the third emission area EA3 of the third pixel PX3. The third color filter CF3 may transmit light of the third color, or in other words, light of the red wavelength band, therethrough. The red wavelength band may be approximately 600 nm to 750 nm. Therefore, the third color filter CF3 may transmit light of the third color among light emitted from the third emission area EA3 therethrough.

Each of the plurality of lenses LNS may be disposed on a corresponding one of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape that is convex in an upward direction.

The filling layer FIL may be disposed on the plurality of lenses LNS. The filling layer FIL may have a suitable refractive index (e.g., a predetermined refractive index) so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, or the like.

The cover layer CVL may be disposed on the filling layer FIL. The cover layer CVL may be a glass substrate, or a polymer resin such as a resin. When the cover layer CVL is the glass substrate, the cover layer CVL may be attached onto the filling layer FIL. In this case, the filling layer FIL may serve to adhere to the cover layer CVL. When the cover layer CVL is the glass substrate, the cover layer CVL may serve as an encapsulation substrate. When the cover layer CVL is the polymer resin such as the resin, the cover layer CVL may be directly applied onto the filling layer FIL.

The polarizing plate POL may be disposed on one surface of the cover layer CVL. The polarizing plate POL may be a structure for reducing or preventing a visibility degradation that may be caused by a reflection of external light. The polarizing plate POL may include a linear polarizing plate and a phase retardation film. For example, the phase retardation film may be a λ/4 plate (quarter-wave plate), but the present disclosure is not limited thereto. However, in case in which the visibility degradation caused by reflection of external light is sufficiently improved by the first to third color filters CF1, CF2, and CF3, the polarizing plate POL may be omitted.

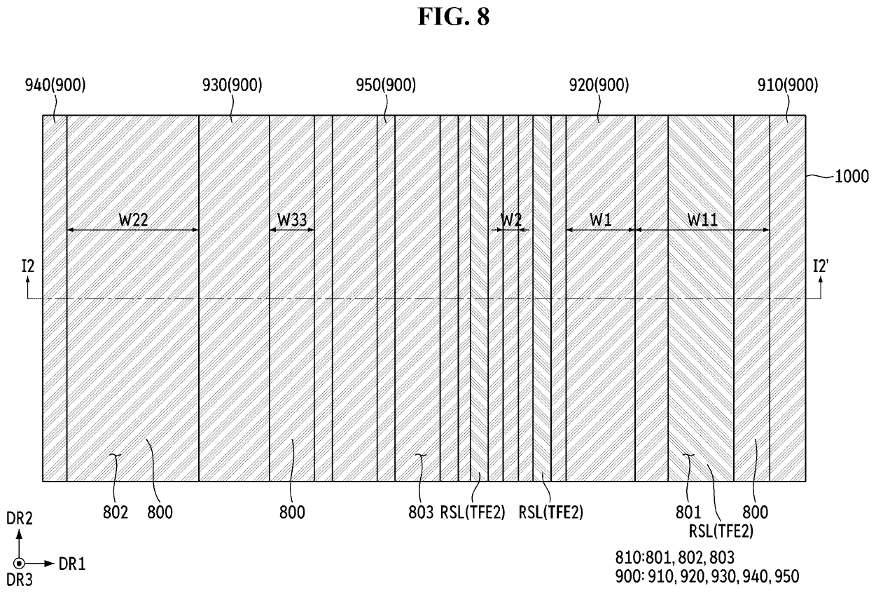

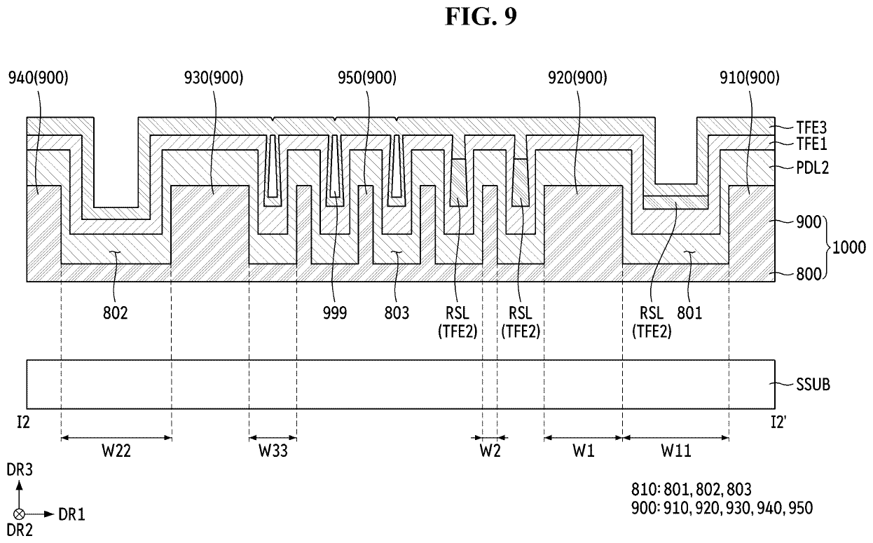

FIG. 8 is an enlarged view of the area A of FIG. 4. FIG. 9 is a cross-sectional view taken along the line I2-I2′ of FIG. 8.

Referring to FIGS. 8 and 9, the display panel may include a flow control layer 1000 disposed on the substrate SSUB. The flow control layer 1000 may include the same material as that of the pixel defining film (e.g., the first pixel defining film PDL1) described above. The flow control layer 1000 may be integrally formed with the pixel defining film (e.g., the first pixel defining film PDL1). The flow control layer 1000 may be disposed at (e.g., in or on) the same layer as that of the pixel defining film (e.g., the first pixel defining film PDL1).

The flow control layer 1000 may include a plurality of protrusion patterns 900. For example, the flow control layer 1000 may include a base layer 800, and the plurality of protrusion patterns 900 protruding from the base layer 800.

The plurality of protrusion patterns 900 may protrude (or may be extended) from the base layer 800 along a direction (e.g., the third direction DR3) facing the flow control layer 1000 from the substrate SSUB. The plurality of protrusion patterns 900 may be disposed in the non-display area NDA.

The plurality of protrusion patterns 900 of the flow control layer 1000 may include main protrusion patterns 910, 920, 930, and 940, and an auxiliary protrusion pattern 950. For example, the plurality of protrusion patterns 900 may include a first main protrusion pattern 910, a second main protrusion pattern 920, a third main protrusion pattern 930, a fourth main protrusion pattern 940, and a plurality of auxiliary protrusion patterns 950.

In a plan view, the plurality of protrusion patterns 900 may each have a closed loop shape surrounding (e.g., around a periphery of) the display area DA. The plurality of protrusion patterns 900 may be disposed at a different distance from the center of the display area DA. The plurality of protrusion patterns 900 may have a greater area (or length) as they are disposed further away from the center of the display area DA. For example, the plurality of protrusion patterns 900 may surround (e.g., around a periphery of) a larger area as they are disposed farther from the center of the display area DA.

In a plan view, the first main protrusion pattern 910 may surround (e.g., around a periphery of) the display area DA. In a plan view, the second main protrusion pattern 920 may surround (e.g., around peripheries of) the display area DA and the first main protrusion pattern 910. In a plan view, the plurality of auxiliary protrusion patterns 950 may surround (e.g., around peripheries of) the display area DA, the first main protrusion pattern 910, and the second main protrusion pattern 920. In a plan view, the plurality of auxiliary protrusion patterns 950 may have a greater length as they are disposed further from the display area DA. In a plan view, the third main protrusion pattern 930 may surround (e.g., around peripheries of) the display area DA, the first main protrusion pattern 910, the second main protrusion pattern 920, and the plurality of auxiliary protrusion patterns 950. In a plan view, the fourth main protrusion pattern 940 may surround (e.g., around peripheries of) the display area DA, the first main protrusion pattern 910, the second main protrusion pattern 920, the plurality of auxiliary protrusion patterns 950, and the third main protrusion pattern 930.

The first main protrusion pattern 910, the second main protrusion pattern 920, the third main protrusion pattern 930, and the fourth main protrusion pattern 940 may be sequentially disposed in the non-display area NDA along the direction facing the edge of the display panel 100 (e.g., the substrate SSUB) from the center of the display area DA. For example, the first main protrusion pattern 910 among the first to fourth main protrusion patterns 910, 920, 930, and 940 may be disposed closest to the center of the display area DA, the second main protrusion pattern 920 among the first to fourth main protrusion patterns 910, 920, 930, and 940 may be disposed next closest to the center of the display area DA, the third main protrusion pattern 930 among the first to fourth main protrusion patterns 910, 920, 930, and 940 may be disposed next closest to the center of the display area DA, and the fourth main protrusion pattern 940 among the first to fourth main protrusion patterns 910, 920, 930, and 940 may be disposed next closest to the center of the display area DA.

The plurality of auxiliary protrusion patterns 950 may be sequentially arranged in the non-display area NDA along a direction facing the edge of the display panel 100 (e.g., the substrate SSUB) from the center of the display area DA. In this case, the plurality of auxiliary protrusion patterns 950 may be disposed between the second main protrusion pattern 920 and the third main protrusion pattern 930.

A width of each of the main protrusion patterns 910, 920, 930, and 940 may be greater than a width of the auxiliary protrusion pattern 950. For example, a width W1 of the second main protrusion pattern 920 may be greater than a width W2 of the auxiliary protrusion pattern 950.

A width of each of the main protrusion patterns 910, 920, 930, and 940 may be the same or substantially the same as each other. For example, a width of the first main protrusion pattern 910, the width W1 of the second main protrusion pattern 920, a width of the third main protrusion pattern 930, and a width of the fourth main protrusion pattern 940 may be the same or substantially the same as each other.

The width W2 of each of the auxiliary protrusion patterns 950 may be the same or substantially the same as each other.

Intervals between the auxiliary protrusion patterns 950 may be the same or substantially the same as each other. For example, the intervals between two adjacent auxiliary protrusion patterns 950 may be the same or substantially the same as the intervals between two other adjacent auxiliary protrusion patterns 950.

In FIGS. 8 and 9, four main protrusion patterns 910, 920, 930, and 940 and four auxiliary protrusion patterns 950 are illustrated, but the number of the main protrusion patterns 910, 920, 930, and 940 and the number of the auxiliary protrusion pattern 950 are not limited thereto, and may be variously modified as needed or desired.

A groove 810 may be disposed between the plurality of protrusion patterns 900. For example, a plurality of grooves 810 may be defined by the base layer 800 and the plurality of protrusion patterns 900.

The plurality of grooves 810 may have a shape that is recessed along a direction from the flow control layer 1000 toward the substrate SSUB (e.g., the reverse direction of the third direction DR3 or a third reverse direction)). The plurality of grooves 810 may be disposed in the non-display area NDA.

The plurality of grooves 810 of the flow control layer 1000 may include, for example, a first main groove 801, a second main groove 802, and an auxiliary groove 803.

In a plan view, the plurality of grooves 810 may each have a closed loop shape surrounding (e.g., around a periphery of) the display area DA. The plurality of grooves 810 may be disposed at a different distance from the center of the display area DA. The plurality of grooves 810 may have a greater area (e.g., length) as they are disposed further away from the center of the display area DA. For example, the plurality of grooves 810 may surround (e.g., around a periphery of) a larger area as they are disposed farther from the center of the display area DA.

In a plan view, the first main groove 801 may surround (e.g., around a periphery of) the display area DA. In a plan view, the plurality of auxiliary grooves 803 may surround (e.g., around peripheries of) the display area DA and the first main groove 801. In a plan view, the plurality of auxiliary grooves 803 may have a greater length as they are disposed further from the display area DA. In a plan view, the second main groove 802 may surround (e.g., around peripheries of) the display area DA, the first main groove 801, and the plurality of auxiliary grooves 803.

The first main groove 801 and the second main groove 802 may be sequentially arranged in the non-display area NDA along a direction facing the edge of the display panel 100 (e.g., the substrate SSUB) from the center of the display area DA. For example, the first main groove 801 among the first and second main grooves 801 and 802 may be disposed closest to the center of the display area DA, and the second main groove 802 may be disposed next closest to the center of the display area DA.

The plurality of auxiliary grooves 803 may be sequentially arranged in the non-display area NDA along a direction facing the edge of the display panel 100 (e.g., the substrate SSUB) from the center of the display area DA. In this case, the plurality of auxiliary grooves 803 may be disposed between the first main groove 801 and the second main groove 802.

The first main groove 801 may be disposed between the adjacent first main protrusion pattern 910 and the second main protrusion pattern 920. In the cross-sectional view of FIG. 9, the first main groove 801 may be a U-shaped space defined by the first main protrusion pattern 910 and the second main protrusion pattern 920.

The second main groove 802 may be disposed between the third main protrusion pattern 930 and the fourth main protrusion pattern 940. In the cross-sectional view of FIG. 9, the second main groove 802 may be a U-shaped space defined by the third main protrusion pattern 930 and the fourth main protrusion pattern 940.

The outermost auxiliary grooves 803 on both sides among the plurality of auxiliary grooves 803 may be disposed between the adjacent main protrusion pattern and the auxiliary protrusion pattern 950. For example, one outermost auxiliary groove 803 (hereinafter, a first outermost auxiliary groove 803) disposed at one edge among the plurality of auxiliary grooves 803 may be disposed between the second main protrusion pattern 920 and the adjacent auxiliary protrusion pattern 950 (hereinafter, a first outermost auxiliary protrusion pattern), and another outermost auxiliary groove 803 (hereinafter, a second outermost auxiliary groove 803) disposed at the other edge among the plurality of auxiliary grooves 803 may be disposed between the third main protrusion pattern 930 and the adjacent auxiliary protrusion pattern 950 (hereinafter, a second outermost auxiliary protrusion pattern 950). In the cross-sectional view of FIG. 9, the first outermost auxiliary groove 803 may be a U-shaped space defined by the base layer 800, the second main protrusion pattern 920, and the first outermost auxiliary protrusion pattern 950. In addition, in a cross-sectional view of FIG. 9, the second outermost auxiliary groove 803 may be a U-shaped space defined by the base layer 800, the third main protrusion pattern 930, and the second outermost auxiliary protrusion pattern 950.

Among the plurality of auxiliary grooves 803, the auxiliary grooves 803 (hereinafter referred to as intermediate auxiliary grooves) between the first outermost auxiliary groove 803 and the second outermost auxiliary groove 803 may be disposed between each of the adjacent auxiliary protrusion patterns 950. In the cross-sectional view of FIG. 9, the intermediate auxiliary groove 803 may be a U-shaped space defined by the base layer 800, any one of the auxiliary protrusion patterns 950, and another adjacent auxiliary protrusion patterns 950 that is adjacent to the one auxiliary protrusion pattern 950.

Even though two main grooves 801 and 802 and five auxiliary grooves 803 are illustrated in FIGS. 8 and 9 according to an embodiment, the number of the main grooves 801 and 802 and the number of the auxiliary grooves 803 are not limited thereto, and may be variously modified as needed or desired.

The first main groove 801 and the auxiliary groove 803 may have different widths from each other. For example, a width W11 of the first main groove 801 may be greater than a width W33 of the auxiliary groove 803.

The second main groove 802 and the auxiliary groove 803 may have different widths from each other. For example, a width W22 of the second main groove 802 may be greater than the width W33 of the auxiliary groove 803.

The width W11 of the first main groove 801 and the width W22 of the second main groove 802 may be the same or substantially the same as each other.

The auxiliary grooves 803 may have the same or substantially the same width W33 as each other.

The interval between the auxiliary grooves 803 may be the same or substantially the same as each other. For example, the interval between the adjacent two auxiliary grooves 803 and the interval between the other adjacent two auxiliary grooves 803 may be the same or substantially the same as each other.

As described above, because the flow control layer 1000 includes the protrusion patterns 900 and the grooves 810, the flow control layer 1000 may have an uneven shape.

A pixel defining film (e.g., a second pixel defining film PDL2) may be disposed on the flow control layer 1000. The second pixel defining film PDL2 may be disposed on the protrusion patterns 900 of the flow control layer 1000. In addition, the second pixel defining film PDL2 may be disposed in the grooves 810 of the flow control layer 1000.

A first encapsulation inorganic film TFE1 may be disposed on the second pixel defining film PDL2. The first encapsulation inorganic film TFE1 may be disposed on the second pixel defining film PDL2 to overlap with the protrusion patterns 900 and the grooves 810 of the flow control layer 1000. In this case, the first encapsulation inorganic film TFE1 may be disposed in the grooves 810 of the flow control layer 1000.

A residual film RSL of the encapsulation organic film TFE2 (e.g., see FIG. 7) may be disposed on the first encapsulation inorganic film TFE1. For example, the residual film RSL may be disposed in at least one groove 810 of the flow control layer 1000. For example, as illustrated in FIGS. 8 and 9, at least a portion of the encapsulation organic film TFE2 (e.g., the residual film RSL of the encapsulation organic film TFE2) may be disposed in each of the first main groove 801 and the two auxiliary grooves 803. In this case, the grooves 810 may not be connected to each other. For example, the residual film RSL overlapping with the first main groove 801, the residual film RSL overlapping with any one auxiliary groove 803, and the residual film RSL overlapping with another auxiliary groove 803 may not be connected to each other and be separated or spaced apart from each other. In addition, the residual film RSL overlapping with each groove 810 may not be connected to the encapsulation organic film TFE2 of the display area DA, and may be separated or spaced apart therefrom.

According to an embodiment, the residual film RSL disposed in the main grooves 801 and 802 may have different thicknesses from that of the residual film RSL disposed in the auxiliary groove 803. For example, as illustrated in FIG. 9, the thickness of the residual film RSL disposed in the first main groove 801 may be less than the thickness of the residual film RSL disposed in the auxiliary groove 803. The thickness may be a size (e.g., a length) in the third direction DR3.

According to an embodiment, the residual film RSL may not be disposed in all of the grooves 810 of the flow control layer 1000.

A second encapsulation inorganic film TFE3 may be disposed on the encapsulation organic film TFE2 and the residual film RSL. The second encapsulation inorganic film TFE3 may be disposed on the residual film RSL to overlap with the protrusion patterns 900 and the grooves 810 of the flow control layer 1000. In this case, the second encapsulation inorganic film TFE3 may be disposed in the grooves 810 of the flow control layer 1000.

When the residual film RSL is disposed in the groove 810, the second encapsulation inorganic film TFE3 may be disposed on the residual film RSL inside the groove 810. In this case, the second encapsulation inorganic film TFE3 may be in contact (e.g., in direct contact) with the residual film RSL inside the groove 810. When the residual film RSL is not disposed in the groove 810, the second encapsulation inorganic film TFE3 may be disposed on the first encapsulation inorganic film TFE1 inside the groove 810. In this case, the second encapsulation inorganic film TFE3 may be in contact (e.g., in direct contact) with the first encapsulation inorganic film TFE1 inside the groove 810.

According to an embodiment, the second encapsulation inorganic film TFE3 may be in contact (e.g., in direct contact) with the first encapsulation inorganic film TFE1 on the protrusion patterns 900.

According to an embodiment, the second encapsulation inorganic film TFE3 disposed on adjacent protrusion patterns 900 may be in contact (e.g., in direct contact) with each other. For example, the second encapsulation inorganic film TFE3 on the third main protrusion pattern 930 (e.g., the second encapsulation inorganic film TFE3 overlapping with the third main protrusion pattern 930) and the second encapsulation inorganic film TFE3 on the auxiliary protrusion pattern 950 adjacent to the third main protrusion pattern 930 (e.g., the second encapsulation inorganic film TFE3 overlapping with the second outermost auxiliary protrusion pattern 950) may be in contact (e.g., in direct contact) with each other.

According to an embodiment, when the residual film RSL is not disposed in the groove 810, a cavity 999 surrounded (e.g., around a periphery thereof) by the second encapsulation inorganic film TFE3 or an empty space may be formed inside the groove 810. For example, at least a portion of the cavity 999 may be disposed inside the groove (e.g., the auxiliary groove 803).

According to an embodiment, at least one auxiliary groove 803 may be formed between the first main groove 801 and the second main groove 802, and accordingly, during the process of forming the encapsulation organic film TFE2, a raw material (e.g., a monomer) of the encapsulation organic film TFE2 may be prevented or substantially prevented from flowing to the edge of the substrate SSUB. For example, the raw material of the encapsulation organic film TFE2 applied on the center of the display area DA of the substrate SSUB may flow toward the edge of the substrate SSUB, and the flow of the raw material of the encapsulation organic film TFE2 may be limited as it fills one or more of the auxiliary grooves 803 between the first main groove 801 and the second main groove 802. In this case, the raw material of the encapsulation organic film TFE2 may also fill the first main groove 801 and the second main groove 802. Accordingly, the flow of the raw material of the encapsulation organic film TFE2 may be controlled by the auxiliary grooves 803 between the first main groove 801 and the second main groove 802 to not spread further to the edge of the second main groove 802. Accordingly, because the encapsulation organic film TFE2 is not formed between the first encapsulation inorganic film TFE1 and the second encapsulation inorganic film TFE3 at the edge of the display panel 100 (e.g., the substrate SSUB), a bonding strength between the first encapsulation inorganic film TFE1 and the second encapsulation inorganic film TFE3 may be improved. Accordingly, the encapsulation organic film TFE2 may not be exposed at the edge of the display panel 100. Thus, the encapsulation state of the display panel 100 may be improved.

In addition, according to an embodiment, because the width W33 of each of the auxiliary grooves 803 may be narrower than the width W11 or W22 of the main groove 801 or 802, and the arrangement interval between the auxiliary grooves 803 may be narrower than the arrangement interval between the main grooves 801 and 802 as illustrated in FIGS. 8 and 9, the residual film RSL disposed in the auxiliary groove 803 may be maintained in a separated state without being connected to the residual film RSL of another groove adjacent to the auxiliary groove 803. Accordingly, even when a portion of the encapsulation organic film TFE2 (e.g., the residual film RSL) is exposed at the edge of the display panel 100, moisture from the outside may be prevented or substantially prevented from spreading to the encapsulation organic film TFE2 disposed in the display area DA of the display panel 100.

In addition, according to an embodiment, by checking or verifying the presence or the absence of a residual film RSL disposed in the auxiliary groove 803, it may be possible to more easily determine how far the raw material for the encapsulation organic film TFE2 has moved from the center of the display area DA. For example, the auxiliary grooves 803 may be used as a ruler to check the extent of the spread of the raw material of the encapsulation organic film TFE2.

In FIG. 9, at least one of the components between the substrate SSUB (e.g., the semiconductor substrate SSUB) and the first pixel defining film PDL1 described above with reference to FIG. 7 may be disposed between the substrate SSUB and the flow control layer 1000. For example, at least one of the plurality of insulating films SINS1 to SINS3 and/or INS1 to INS11 of FIG. 7 may be disposed between the substrate SSUB and the flow control layer 1000. In addition, at least one conductive layer disposed at (e.g., in or on) the same layer as that of at least one of the plurality of conductive layers ML1 to ML8 of FIG. 7 may be further disposed between the substrate SSUB and the flow control layer 1000. Further, at least one reflective electrode disposed at (e.g., in or on) the same layer as that of at least one of the plurality of reflective electrodes RL1 to RL4 of FIG. 7 may be further disposed between the substrate SSUB and the flow control layer 1000.

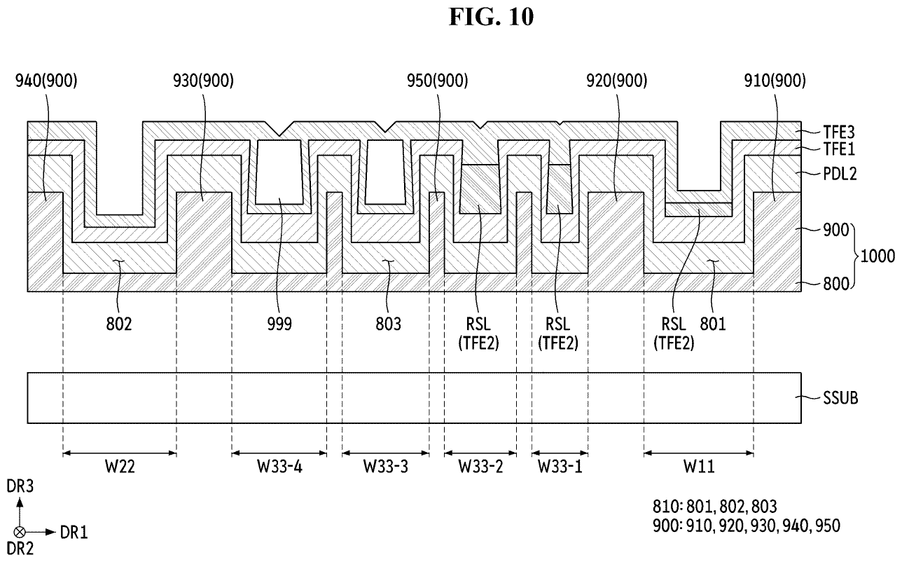

FIG. 10 is a cross-sectional view of a display device according to an embodiment.

The display device 10 illustrated in FIG. 10 may be different from the display device 10 described above with reference to FIG. 9, in that the auxiliary grooves 803 may have different sizes from each other, and thus, redundant description thereof may not be repeated hereinafter, and the differences may be mainly described in more detail below.

As illustrated in FIG. 10, the auxiliary grooves 803 may have a gradually increasing width along the direction facing the edge of the display panel 100 (e.g., the substrate SSUB) from the center of the display area DAA.

For example, among the four auxiliary grooves 803, the auxiliary groove 803 closest to the center of the display area DAA may have the smallest width W33-1. Among the four auxiliary grooves 803, the auxiliary groove 803 disposed furthest from the center of the display area DAA may have the largest width W33-4. When the four auxiliary grooves 803 of FIG. 10 are defined as the first auxiliary groove 803, the second auxiliary groove 803, the third auxiliary groove 803, and the fourth auxiliary groove 803 in the order of closest proximity to the first main groove 801, a width W33-2 of the second auxiliary groove 803 may be greater than the width W33-1 of the first auxiliary groove 803, a width W33-3 of the third auxiliary groove 803 may be greater than the width W33-2 of the second auxiliary groove 803, and the width W33-4 of the fourth auxiliary groove 803 may be greater than the width W33-3 of the third auxiliary groove 803.

According to an embodiment, the auxiliary protrusion patterns 950 of FIG. 10 may have the same or substantially the same width as each other.

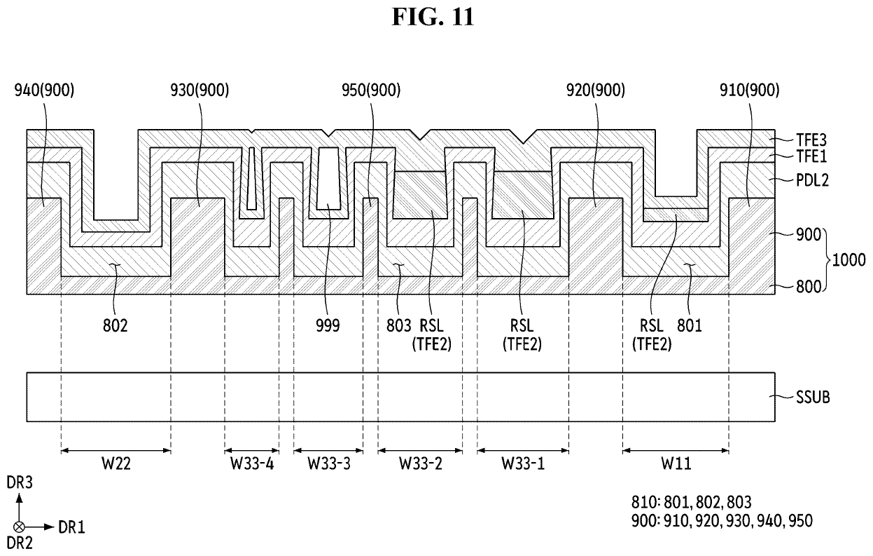

FIG. 11 is a cross-sectional view of a display device 10 according to an embodiment.

The display device 10 of FIG. 11 may be different from the display device 10 described above with reference to FIG. 9, in that the auxiliary grooves 803 may have different sizes from each other, and thus, redundant description may not be repeated hereinafter, and the differences may be mainly described in more detail below.

As illustrated in FIG. 11, the auxiliary grooves 803 may have a gradually decreasing width along the direction facing the edge of the display panel 100 (e.g., the substrate SSUB) from the center of the display area DAA.

For example, among the four auxiliary grooves 803, the auxiliary groove 803 closest to the center of the display area DAA may have the largest width W33-1. Among the four auxiliary grooves 803, the auxiliary groove 803 disposed furthest from the center of the display area DAA may have the smallest width W33-4. When the four auxiliary grooves 803 of FIG. 11 are defined as the first auxiliary groove 803, the second auxiliary groove 803, the third auxiliary groove 803, and the fourth auxiliary groove in the order of closest proximity to the first main groove 801, a width W33-2 of the second auxiliary groove 803 may be smaller than the width W33-1 of the first auxiliary groove 803, a width W33-3 of the third auxiliary groove 803 may be smaller than the width W33-2 of the second auxiliary groove 803, and the width W33-4 of the fourth auxiliary groove 803 may be smaller than the width W33-3 of the third auxiliary groove 803.

According to an embodiment, the auxiliary protrusion patterns 950 of FIG. 11 may have the same or substantially the same width as each other.

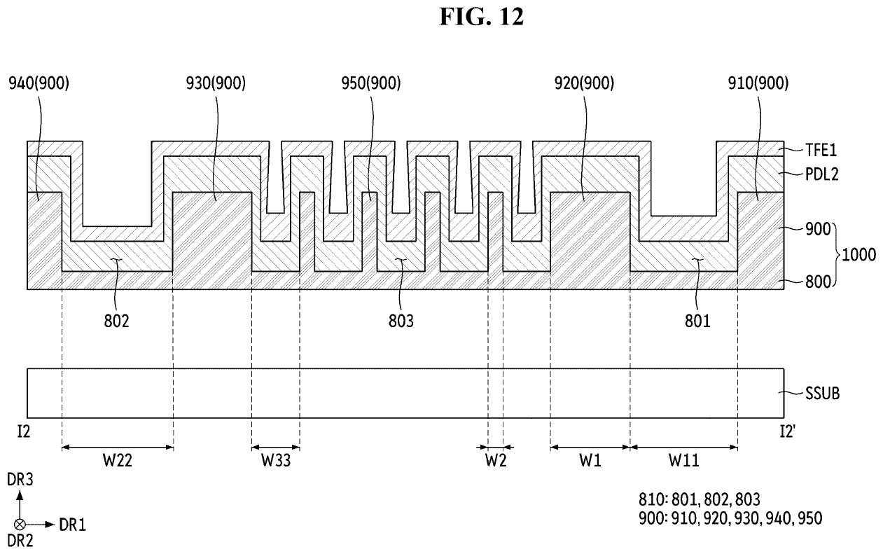

FIGS. 12 through 14 are diagrams illustrating some processes of a method for fabricating a display device according to an embodiment.

First, referring to FIG. 12, a flow control layer 1000 including a plurality of protrusion patterns 900 and a plurality of grooves 810 may be formed on a substrate SSUB. A second pixel defining film PDL2 may be formed on the flow control layer 1000, and a first encapsulation inorganic film TFE1 may be formed on the second pixel defining film PDL2.

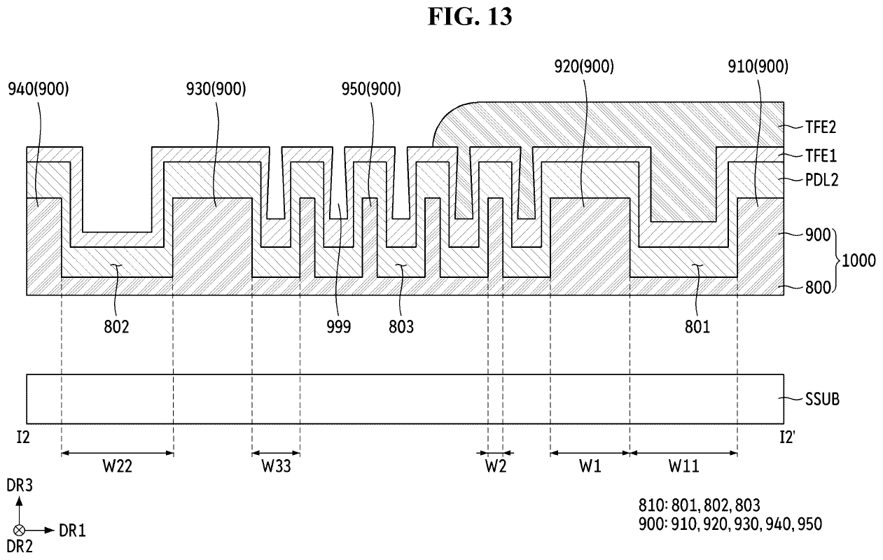

Next, referring to FIG. 13, an encapsulation organic film TFE2 may be disposed on the first encapsulation inorganic film TFE1. For example, a raw material of the encapsulation organic film TFE2 including a monomer may be applied on the first encapsulation inorganic film TFE1. In this case, the raw material of the encapsulation organic film TFE2 may be applied on the first encapsulation inorganic film TFE1 in a deposition or ink-jet method. Thereafter, as the raw material applied on the first encapsulation inorganic film TFE1 is cured, the encapsulation organic film TFE2 may be formed on the first encapsulation inorganic film TFE1.

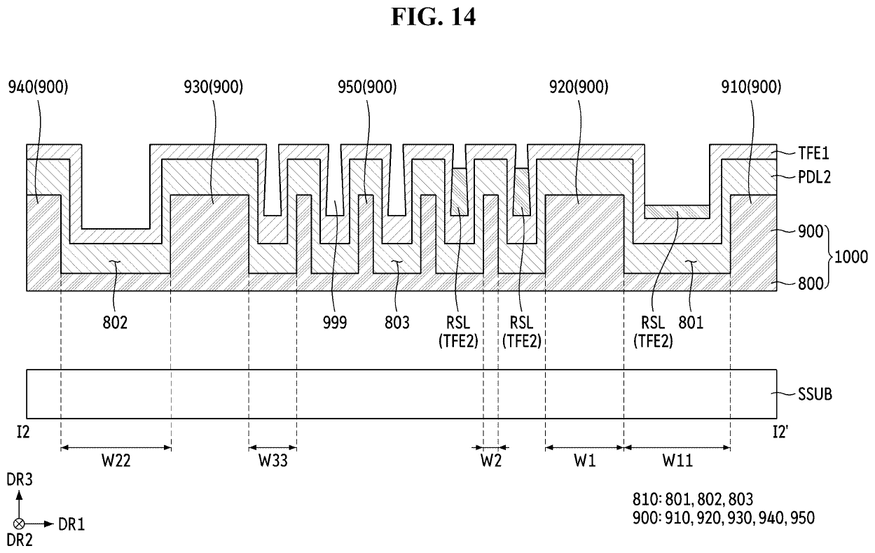

Subsequently, referring to FIG. 14, a portion of the encapsulation organic film TFE2 disposed at the edge of the substrate SSUB including the grooves 810 may be selectively removed. For example, the encapsulation organic film TFE2 of the edge of the substrate SSUB may be removed through an ashing process. In this case, a portion of the encapsulation organic film TFE2 outside the groove 810 may be removed as illustrated in FIG. 14. In this case, because the width of the auxiliary groove 803 may be relatively narrow and a depth thereof may be relatively deep, a portion of the encapsulation organic film TFE2 inside the auxiliary groove 803 may remain without being removed even after the ashing process. For example, the portion of the encapsulation organic film TFE2 inside the auxiliary groove 803 may remain as the residual film RSL.

Next, referring to FIG. 9, a second encapsulation inorganic film TFE3 may be formed on the entire or substantially the entire surface of the substrate SSUB including the residual film RSL. For example, the second encapsulation inorganic film TFE3 may be formed on the first encapsulation inorganic film TFE1, the encapsulation organic film TFE2, and the residual film RSL.

According to an embodiment, an embossed protrusion may be formed instead of the engraved groove 810.

In addition, according to an embodiment, the encapsulation layer TFE may have a quadruple layered structure. For example, the encapsulation layer TFE may further include an auxiliary inorganic film disposed between the second encapsulation inorganic film TFE3 and an organic film APL (e.g., see FIG. 7). The auxiliary inorganic film may include, for example, titanium oxide (TiOₓ) or aluminum oxide (AlOx) (e.g., Al₂O₃). The auxiliary inorganic film may be formed through an atomic layer deposition (ALD) process.

The display device according to some embodiments may be applied to various suitable electronic devices. The electronic devices according to some embodiments may include the display device as described above, and may further include various suitable modules or devices having additional functions in addition to that of the display device.

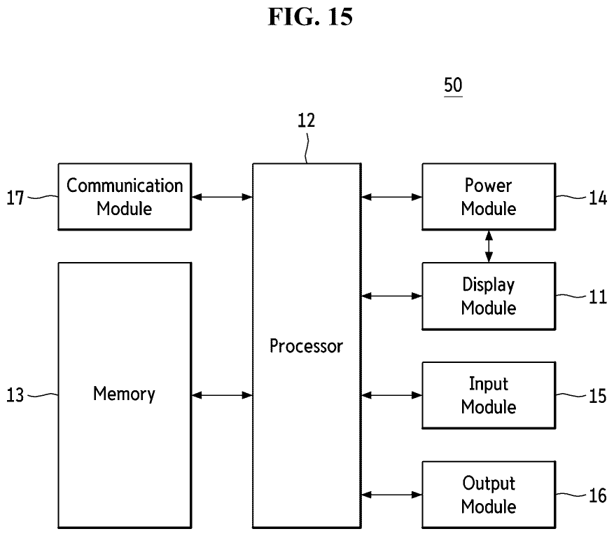

FIG. 15 is a block diagram of an electronic device according to an embodiment. Referring to FIG. 15, the electronic device 50 according to an embodiment may include a display module, a processor 12, a memory 13, and a power module 14. The electronic device 5000 may further include an input module 14, a non-image output module 15, and/or a communication module 16.

The electronic device 50 may output various suitable information in the form of images through the display module 11. When the processor 12 executes an application stored in the memory 13, image information provided by the application may be provided to the user through the display module 1100. The power module 14 may include a power supply module, such as a power adapter or a battery device, and a power conversion module that converts the power supplied by the power supply module to generate power used for the operations of the electronic device 5000. The input module 14 may provide input information to the processor 12 and/or the display module 11. The non-image output module 15 may receive information other than images transmitted from the processor 12, such as sound, haptics, and light, and may provide the information to the user. The communication module 16 may be responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes the display module 11, and the processor 12, the memory 13, and the power module 14 may be provided in the form of other devices within the electronic device 11 other than the display device.

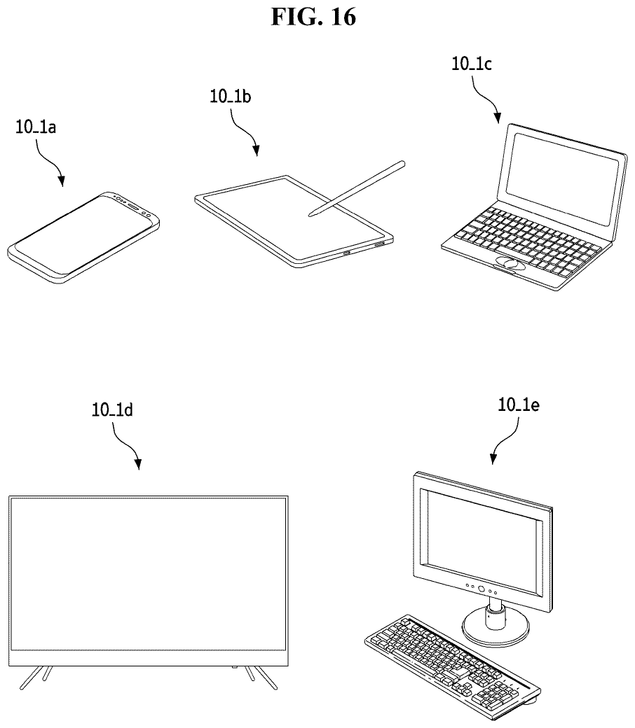

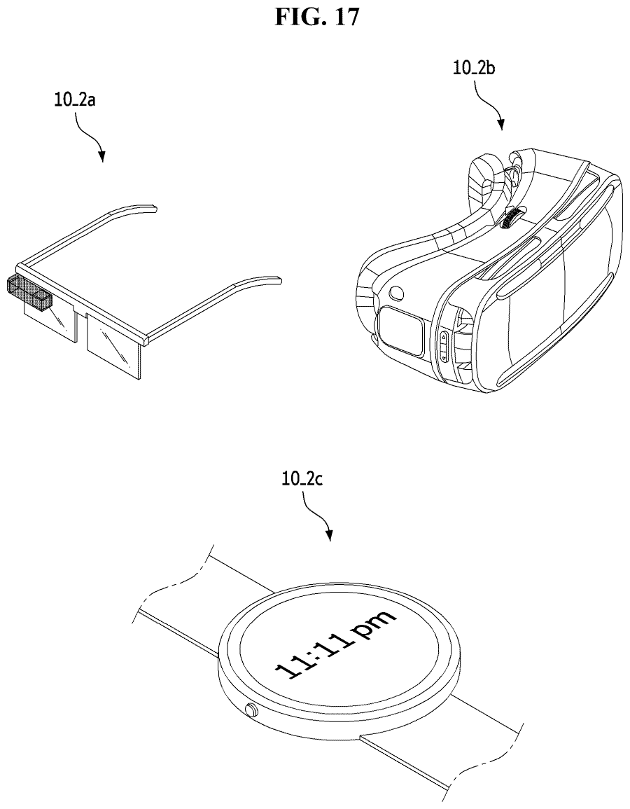

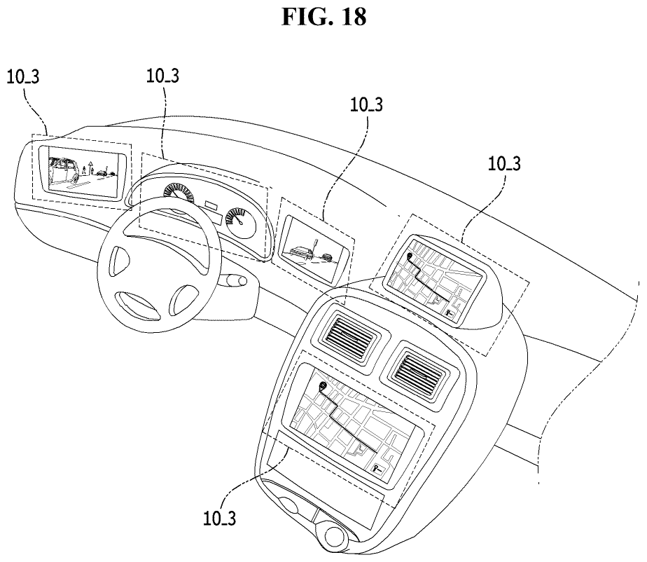

FIG. 16 illustrates schematic diagrams of some electronic devices according to some embodiments. FIG. 17 illustrates schematic diagrams of some electronic devices according to some embodiments. FIG. 18 illustrates schematic diagrams of some electronic devices according to some embodiments. FIGS. 16 to 18 illustrate examples of various suitable electronic devices to which the display device according to some of the embodiments described above may be applied.

FIG. 16 illustrates a smartphone 10_1a, a tablet PC 10_1b, a laptop 10_1c, a TV 10_1d, and a desk monitor 10_1e as some examples of the electronic devices.

In addition to the display module 11, the smartphone 10_1a may include an input module, such as a touch sensor, and a communication module. The smartphone 10_1a may process information received through the communication module or other input modules, and may display the information through the display module of the display device.

The tablet PCs 10_1b, the laptops 10_1c, the TVs 10_1d, and the desk monitors 10_1e may also include display modules and input modules, similar to those of the smartphones 10_1, and may additionally include communication modules in some cases.

FIG. 17 shows an example of an electronic device including a display module that is applied to a wearable electronic device. The wearable electronic device may be a smart glasses 10_2a, a head-mounted display 10_2b, a smart watch 10_2c, or the like.

The smart glasses 10_2a and the head-mounted display 10_2b may include a display module that emits a display image, and a reflector that reflects the emitted display image and provides it to the user's eyes, thereby providing a virtual reality or augmented reality screen to the user.

The smart watch 10_2c includes a biometric sensor as an input device, and may provide biometric information recognized by the biometric sensor to the user through the display module.

FIG. 18 illustrates an electronic device including a display module that is applied to a vehicle. For example, the electronic device 10_3 may be applied to a dashboard, a center fascia, and the like of a vehicle, may be applied to a CID (Center Information Display) placed on a dashboard of a vehicle, or may be applied to a room mirror display replacing a side mirror.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a first electrode in a display area of the substrate;
a light emitting layer on the first electrode;
a pixel defining film on the light emitting layer;
a second electrode on the pixel defining film; and
a flow control layer comprising:
a first main groove in a non-display area of the substrate;
a second main groove in the non-display area; and
an auxiliary groove in the non-display area between the first main groove and the second main groove.

2. The display device of claim 1, wherein a width of the auxiliary groove is different from a width of the first main groove.

3. The display device of claim 2, wherein the width of the auxiliary groove is smaller than the width of the first main groove.

4. The display device of claim 1, wherein a width of the first main groove and a width of the second main groove are the same as each other.

5. The display device of claim 1, further comprising:
a first encapsulation inorganic film on the flow control layer;
an encapsulation organic film on the first encapsulation inorganic film; and
a second encapsulation inorganic film on the encapsulation organic film.

6. The display device of claim 5, wherein a residual film of the encapsulation organic film is located in at least one of the first main groove, the second main groove, or the auxiliary groove of the flow control layer.

7. The display device of claim 6, wherein the auxiliary groove comprises a plurality of auxiliary grooves, and
wherein the residual film comprises a plurality of residual films in the plurality of auxiliary grooves, respectively, the plurality of residual films being spaced from each other.

8. The display device of claim 5, wherein a residual film located in at least one of the first main groove or the second main groove has a thickness different from that of a residual film located in the auxiliary groove.

9. The display device of claim 8, wherein the thickness of the residual film in the auxiliary groove is greater than the thickness of the residual film in the at least one of the first main groove or the second main groove.

10. The display device of claim 5, wherein a cavity surrounded by the second encapsulation inorganic film is located in the auxiliary groove.

11. The display device of claim 5, wherein the pixel defining film comprises:
a first pixel defining film; and
a second pixel defining film on the first pixel defining film.

12. The display device of claim 11, wherein the flow control layer is located at the same layer as that of the first pixel defining film.

13. The display device of claim 11, wherein the second pixel defining film is further located between the flow control layer and the first encapsulation inorganic film.

14. The display device of claim 1, wherein the auxiliary groove comprises a plurality of auxiliary grooves, and
wherein the plurality of auxiliary grooves has the same width as each other.

15. The display device of claim 14, wherein an interval between adjacent auxiliary grooves from among the plurality of auxiliary grooves is the same as an interval between other adjacent auxiliary grooves from among the plurality of auxiliary grooves.

16. The display device of claim 1, wherein the auxiliary groove comprises a plurality of auxiliary grooves, and
wherein widths of the plurality of auxiliary grooves increase as they become farther from the center of the display area.

17. The display device of claim 1, wherein the auxiliary groove comprises a plurality of auxiliary grooves, and
wherein widths of the plurality of auxiliary grooves decrease as they become farther from the center of the display area.

18. The display device of claim 1, wherein the flow control layer comprises:
a base layer; and
a plurality of protrusion patterns protruding from the base layer to define the first main groove, the second main groove, and the auxiliary groove.

19. A method for fabricating a display device, the method comprising:
forming a flow control layer on a substrate, the flow control layer having a first main groove, a second main groove, and an auxiliary groove;
forming a pixel defining film on the flow control layer;
forming a first encapsulation inorganic film on the pixel defining film;
forming an encapsulation organic film on the first encapsulation inorganic film; and
forming a residual film in at least one of the first main groove, the second main groove, or the auxiliary groove by selectively removing a portion of the encapsulation organic film formed in a non-display area of the substrate.

20. An electronic device comprising:
a display device comprising a screen,
wherein the display device comprises:
a substrate;
a first electrode in a display area of the substrate;
a light emitting layer on the first electrode;
a pixel defining film on the light emitting layer;
a second electrode on the pixel defining film; and
a flow control layer comprising:
a first main groove in a non-display area of the substrate;
a second main groove in the non-display area; and
an auxiliary groove between the first main groove and the second main groove in the non-display area.
